(19) United States
(12) Patent Application Publication
(10) Pub. No.: US 2025/0070821 A1
(43) Pub. Date: Feb. 27, 2025

(54) HELICOPTER AUDIO CABLE TEST SYSTEM AND METHOD

(71) Applicants: Skylar James Schiman Finn, Morgantown, KY (US); Civil-Military Innovation Institute Inc., Morgantown, WV (US)

(72) Inventors: Skylar James Schiman Finn, Union, KY (US); Benjamin Jay Borger, Fayetteville, NC (US); Yurij Wowczuk, Morgantown, WV (US)

(21) Appl. No.: 18/814,048

(22) Filed: Aug. 23, 2024

Related U.S. Application Data
(60) Provisional application No. 63/566,967, filed on Mar. 19, 2024.
(60) Provisional application No. 63/534,468, filed on Aug. 24, 2023.

(51) Int. Cl. H04B 3/46; G08B 7/06; H04R 29/00

(52) U.S. Cl. CPC H04B 3/46; G08B 7/06; H04R 29/00

(57) ABSTRACT

Disclosed are an intercommunication system cable test method and a ruggedized, intercommunication system cable test unit. The intercommunication system cable test unit may include end-to-end test circuitry, a power source, output devices, and one or more connection points. The power source is contained within the portable ruggedized, intercommunication system cable test unit. The one or more connection points may be coupled to the end-to-end test circuitry and be operable to couple with military-specified communication cable connectors of an intercommunication system cable. The end-to-end test circuitry may be operable to apply a test signal at a respective input to each respective pin of the predetermined military-specified communication connector, generate an output signal based on receipt of the applied test signal, and apply the output signal to the output device indicating a response of the end-to-end test circuitry to the applied test signal.

### CROSS-REFERENCE TO RELATED APPLICATIONS

This application claims priority to and the benefit of U.S. Provisional Patent Application No. 63/566,967, filed Mar. 19, 2024, and U.S. Provisional Patent Application No. 63/534,468, filed Aug. 24, 2023, each of which are hereby incorporated by reference in their entireties for all purposes.

### GOVERNMENT LICENSE RIGHTS

This invention was made with government support under Cooperative Agreement No. W911NF2120078 awarded by the U.S. Dept of Defense Army Research Lab (ARL). The government has certain rights in this invention.

### BACKGROUND

The modern day workhorse for military transport of troops and equipment is the helicopter. The coordination between the helicopter pilots and crew members is of utmost most importance to efficient and successful execution of the mission, and effective communication between pilots and crew members is vital. Wireless communication may be unreliable due to the harsh flight environment as well as potential interference from opposing forces. As a result, cables connect various headset connection points within the helicopter or even on individual crew members. The cables may lay across cargo, such as equipment, pallets, troops and the like, within the helicopter, which may provide situations in which the cables are pinched, crushed, tugged, bent, and subjected to other abuse. Eventually, after enough abuse, the cables degrade to a point where communication between crew members and/or pilots are affected.

Cables are typically formed with an outer sheath that surrounds several separately insulated wires, which each may have tens to hundreds of smaller wires that enable the cable to be flexible and therefore provide the crew members and pilots with a range of motion necessary for them to perform their respective jobs. The cables terminate in different connection types.

Over time, however, the smaller wires break due to abuse and extended use, and the several separate wires, while insulated may rub together, be pinched or the like, which may cause the smaller wires within each separate wire to make contact with one another resulting in a short circuit.

In addition, all of the wires in the cables have termination points at the ends of the cable into a connector to communication device or communication headset connection point. These termination points within the connectors can also be sources of degradation because the cables flex at the point of connection, are tugged during use and when disconnecting, and the like.

Fortunately, the cables can be repaired but troubleshooting the cable to determine the cause of the failure can be tedious. Visible physical damage is an obvious indicator, but often visible physical damage is not evident because the damage is within the several wires and smaller wires inside the outer sheath of the cable. Cable testing devices are known, but none that are directed to the explicit needs of a helicopter crew. Typically, troubleshooting of a helicopter communication cable is performed by a technician using a digital multimeter to measure resistance of each particular wire of the several wires of the cable and comparing the measured resistance to a specification sheet. In addition, the technician has to determine whether the termination points are also undamaged, which may also consume a substantial amount of time.

What is needed to assist the technicians in evaluating the helicopter communication cables is a cable test device and a testing process using the cable test device that quickly and efficiently indicates to the technician the cause of any failure or damage to the cable so the technician can more quickly begin repairing the damaged cable.

### BRIEF SUMMARY

In one aspect, a ruggedized, intercommunication system cable test unit is provided that may include end-to-end test circuitry, a power source, output devices, and one or more connection points. The output devices may include light source or an audio source. The one or more connection points may be coupled to the end-to-end test circuitry and be operable to couple with military-specified communication cable connectors of an intercommunication system cable. The one or more connection points may include a respective input configured to receive a respective pin of a predetermined military-specified communication cable connector. The end-to-end test circuitry may be operable to apply a test signal at the respective input to each respective pin of the predetermined military-specified communication connector, generate an output signal based on receipt of the applied test signal, and apply the output signal to the output device indicating a response of the end-to-end test circuitry to the applied test signal.

In another aspect, a ruggedized, intercommunication system cable test unit is provided that includes an audio jack, a communication system connector, and end-to-end test circuitry. The audio jack may be operable to connect to an audio connection end of an intercommunication system cable. The communication system connector may be operable to connect to a communication system connector of the intercommunication system cable, where the communication system connector is specific to a type of military aircraft and the communication system connector connects a plurality. The end-to-end test circuitry may be configured to test integrity of an intercommunication system cable when the intercommunication system cable is coupled to the audio jack and the communication system connector, where the end-to-end test circuitry is operable to detect whether an open circuit is present in the intercommunication system cable, and in response to detecting presence of the open circuit, produce an output indicating the presence of the open circuit.

In yet another aspect, a method of using a ruggedized, intercommunication system cable test unit to test the integrity of an intercommunication system cable is provided. The method includes a step of coupling a first end of a military aircraft specific communication cable to a communication system connector of the ruggedized, intercommunication system cable test unit specific to the military aircraft specific communication cable. A second end of the military aircraft specific communication cable is coupled to an audio jack of the intercommunication system cable test device. The end-to-end test circuitry of the ruggedized, intercommunication system cable test unit applies an audio test signal to the military aircraft specific communication cable, and an indication of the open circuit status of the military aircraft specific communication cable is generated.

### BRIEF DESCRIPTION OF THE DRAWINGS

To easily identify the discussion of any particular element or act, the most significant digit or digits in a reference number refer to the figure number in which that element is first introduced.

FIG. 1 illustrates an example of a flight environment in which intercommunication system cables are utilized.

FIG. 2 illustrates an example of a first end of an intercommunication system cable according to the disclosed subject matter.

FIG. 3 illustrates an example of a second end of an intercommunication system cable according to the disclosed subject matter.

FIG. 4 illustrates an example of an audio jack structure suitable for use with the disclosed subject matter.

FIG. 5A illustrates an isometric-view of an example of a ruggedized, intercommunication system cable test unit in accordance with the disclosed subject matter.

FIG. 5B illustrates a top-view of an example of a ruggedized, intercommunication system cable test unit in accordance with the disclosed subject matter.

FIG. 6 illustrates exemplary isometric top and bottom views of another example of a ruggedized, intercommunication system cable test unit in accordance with the disclosed subject matter.

FIG. 7 illustrates an example of a schematic diagram of end-to-end test circuitry according to an embodiment of the disclosed subject matter.

FIG. 8 illustrates an exemplary method of using at least one embodiment of the ruggedized, intercommunication system cable test unit as described herein.

FIG. 9A illustrates a first part of another exemplary method of using at least one embodiment of the ruggedized, intercommunication system cable test unit as described herein.

FIG. 9B illustrates the second part of the other exemplary method of using at least one embodiment of the ruggedized, intercommunication system cable test unit as described herein.

FIG. 10A illustrates alternative exemplary housings for the ruggedized, intercommunication system cable test unit according to different aspects of the disclosed subject matter.

FIG. 10B illustrates yet another exemplary housing for the ruggedized, intercommunication system cable test unit according to different aspects of the disclosed subject matter.

FIG. 11A illustrates a top-view of an exemplary circuit board for implementing aspects of the disclosed subject matter in accordance with at least one embodiment.

FIG. 11B illustrates a bottom-view of the exemplary circuit board of FIG. 11A for implementing aspects of the disclosed subject matter in accordance with at least one embodiment.

FIG. 12A illustrates a top-view of another exemplary circuit board for implementing aspects of the disclosed subject matter in accordance with one embodiment.

FIG. 12B illustrates a bottom-view of the other exemplary circuit board of FIG. 12A for implementing aspects of the disclosed subject matter in accordance with one embodiment.

FIG. 13 illustrates a front-view and a back-view of yet another exemplary circuit board for implementing aspects of the disclosed subject matter in accordance with one embodiment.

FIG. 14A illustrates a top-view of a further exemplary circuit board for implementing aspects of the disclosed subject matter in accordance with one embodiment.

FIG. 14B illustrates a bottom-view of the further exemplary circuit board of FIG. 14A for implementing aspects of the disclosed subject matter in accordance with one embodiment.

FIG. 15 illustrates an example of another schematic diagram of end-to-end test circuitry according to an embodiment of the disclosed subject matter.

FIG. 16 illustrates a high level example of end-to-end test circuitry according to the disclosed subject matter.

FIG. 17 illustrates exemplary time-saving aspects derived from using the disclosed subject matter.

### DETAILED DESCRIPTION

The following describes different examples of a ruggedized, intercommunication system cable test unit that is configured to test the integrity of intercommunication system cables. The ruggedized, intercommunication system cable test unit is portable and does not require external power sources, alternating current (AC) power, a transformer, or voltage converters.

“Integrity” refers to structural capability of an intercommunication system cable to carry signals per the specifications of the intercommunication system cable. Integrity can be categorized as either ‘intact” or “operational” meaning the structural capability of the intercommunication system cable remains within specifications, or “degraded” meaning the structural capability of the intercommunication system cable is not within specifications. “Degraded integrity” can be caused by structural defects such as “open” circuits, “short” circuits, and the like. An “open circuit” as used herein may be due to breaks or separation of wires along the length of the cable or at connectors coupled to the wires at either end of the intercommunication system cable as a result the communication signals suffer loss and cannot pass through the cable with sufficient clarity. The open circuits may be intermittent depending upon the how and where the “open circuit” occurs in the cable. A “short circuit” is when wires of adjacent conductors touch one another and thereby preventing the communication signal (at its minimum specification) from traveling to its output. While the open circuit and short circuit definitions provided above indicate the communication signal does not reach its output, there are instances where the damage to the cable is not that severe and the communication signal intermittently reaches its output. As such, intermittent short circuits and intermittent open circuits are still categorized, respectively as a short circuit and an open circuit. An intercommunication system cable with one or more of the open circuit, short circuit, intermittent short circuits, and intermittent open circuits may be considered to have “degraded integrity.”

Different embodiments of the ruggedized, intercommunication system cable test unit may be configured to conduct different tests. In some examples, the ruggedized, intercommunication system cable test unit is not configured to detect short circuits or resistive/intermittent connections. In other examples, the ruggedized, intercommunication system cable test unit does not indicate the location of a failure/break. Because the intercommunication system cables are audio cables, there are signal quality issues as well, and in some embodiments, audio signals may be input to the cable and the end-to-end test circuitry may be configured to evaluate the signal quality using a speaker, total harmonic distortion (THD) measurement, or another approach.

Mechanically, the ruggedized, intercommunication system cable test unit may be subjected to harsh conditions when deployed for flight operations or field conditions. It would be beneficial if the ruggedized, intercommunication system cable test unit had a housing configured to meet military specifications or industrial specifications.

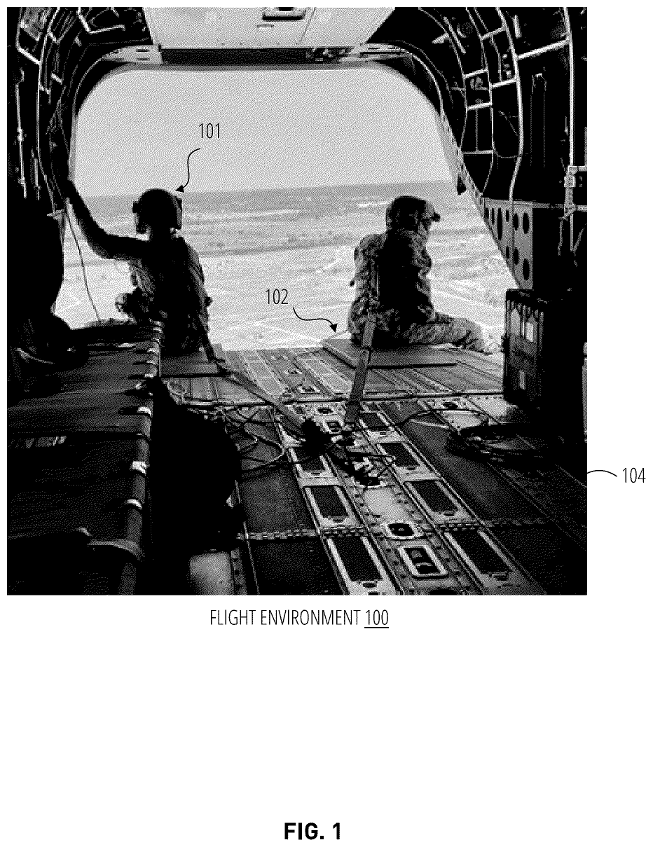

FIG. 1 illustrates an example of a flight environment in which intercommunication system cables are utilized. It may be helpful to understand the conditions and environment that an intercommunication system cable encounters. The flight environment 100 is an aircraft, such as a helicopter, in which the helicopter crew members must communicate verbally. The crew members are equipped with audio headphones and microphones, such as crew member headphone/microphone 101 that are coupled to the communication system of the aircraft via intercommunication system cables, such as intercommunication system cable 102. An “intercommunication system cable” refers to a wired cable that connects an aircraft crew member headset to an aircrafts' communication system to facilitate in aircraft communication and depending upon configuration communication with entities external to the aircraft. The wired cable may terminate in connectors at both ends of the length of cable. A first end may terminate in a military-specified communication connector and a second end that terminates in an audio jack. Intercommunication system cables may be configured in various lengths from a few feet to tens of feet long to accommodate a particular job of a crew member (e.g., pilots may have cables of shorter lengths as compared to a crew chief or cargo master).

An example of the lengths of intercommunication system cables is illustrated by coiled intercommunication system cable 104. One end of the coiled intercommunication system cable 104 may be coupled to a crew member headphone/microphone 101 and the other to the aircraft communication system.

Due to the harsh conditions and abuse suffered by the intercommunication system cables in the flight environment 100, the integrity of the intercommunication system cables frequently degrades.

Different aircraft may have different types of intercommunication system cables. For example, one type of aircraft, such as a UH-60 “Blackhawk,” may have an intercommunication system cable that has connectors at either end of the cable that may be different from an intercommunication system cable for another aircraft, such as the UH-47 “Chinook.”

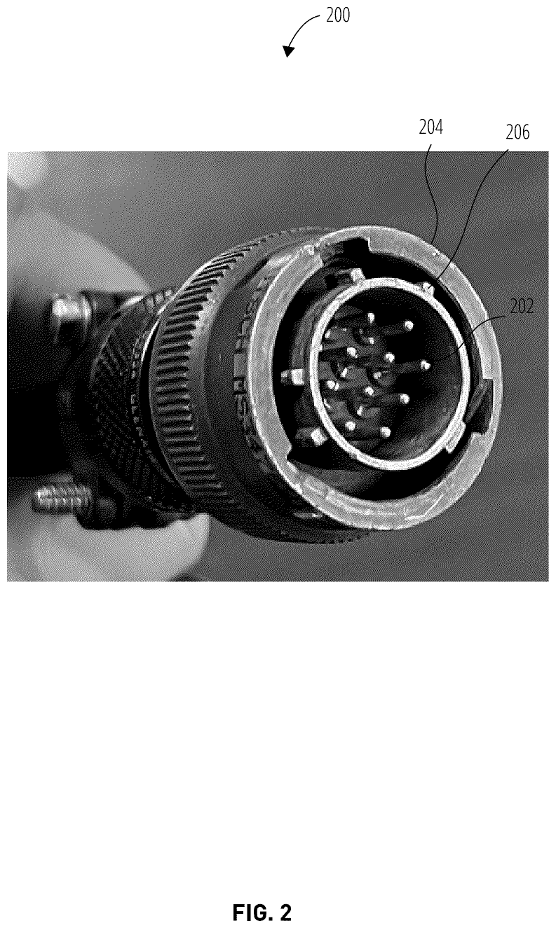

FIG. 2 illustrates an example of a first end of an intercommunication system cable according to the disclosed subject matter. In this example of an aircraft-specific intercommunication system cable (such as 102 in FIG. 1), the first end connector 200 includes pins 202, an outer surface 204, and an alignment key 206.

The ruggedized, intercommunication system cable test unit is configured with a connection point (both shown in a later example) that enables the outer surface 204 of the first end connector 200 of the military-specified communication cable to be affixed to the ruggedized, intercommunication system cable test unit for testing. The alignment key 206 may be set so the intercommunication system cable is connected in the proper orientation to the communication system connector of the aircraft communication system and the ruggedized, intercommunication system cable test unit.

The pins 202 may be coupled to individual conductors within the intercommunication system cable that enable communication with specific crew members (e.g., crew chief with pilot, or crew chief with other crew member, etc.), external communication systems (e.g., radio frequency communication with flight controller or ground crew member), or all crew members on the aircraft. Each of the individual conductors within the intercommunication system cable may be discrete signal paths for audio signals, and test signals. When the intercommunication system cable is being tested, the respective individual conductors, respective pins of the pins 202, and other parts of the intercommunication system cable may form a test signal pathway (described in more detail with reference to a later example).

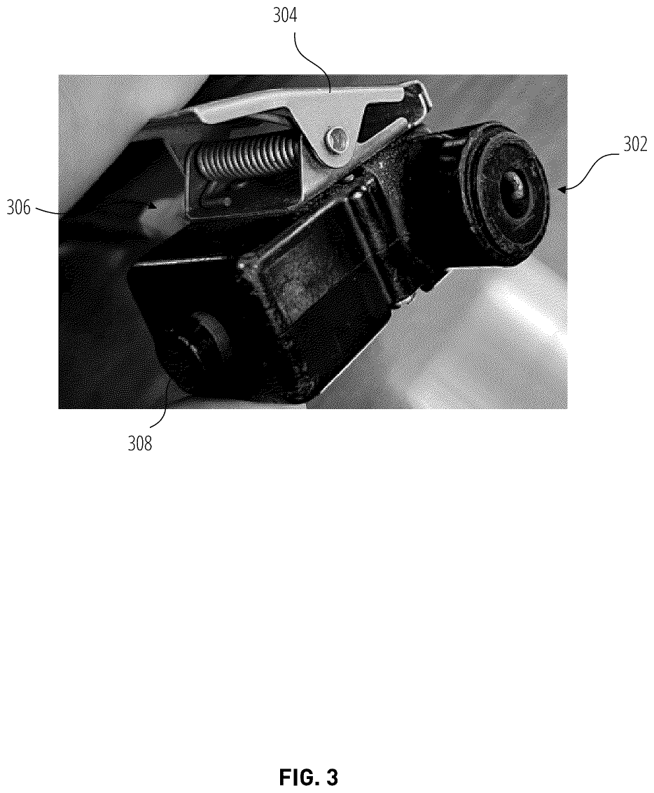

A first end connector 200 of the intercommunication system cable was described with reference to FIG. 2, but the intercommunication system cable also has a second end that terminates in a different type of connector, or in this example, an audio jack. FIG. 3 illustrates an example of the second end of an intercommunication system cable according to the disclosed subject matter. The second end of the intercommunication system cable is the audio jack. The second end of the intercommunication system cable may include an audio jack 302, a clip 304, an intercommunication system cable 306, and a push-to-talk button 308. Not shown is a selector switch that switches between different conductors to enable communication with different crew members and/or entities, such as flight control and the like.

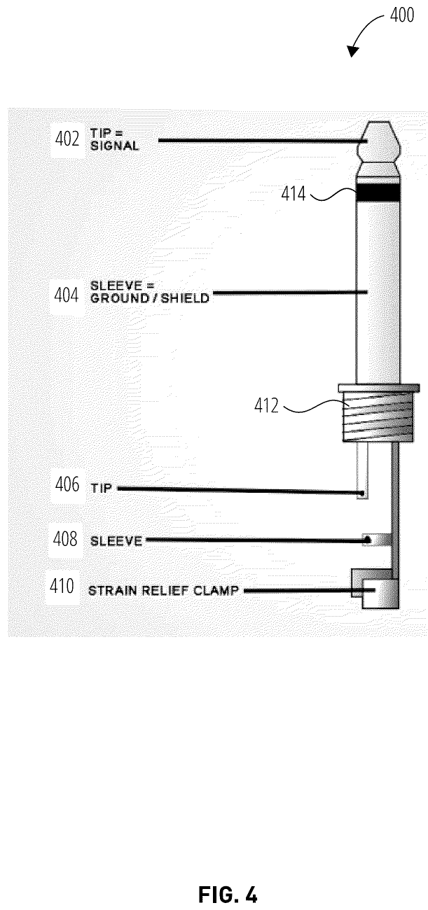

The audio jack 302 is configured to receive an audio plug (discussed in more detail with reference to FIG. 4) to enable a connection of the crew member headphone/microphone to the aircraft communication system. The audio jack 302 is coupled to the intercommunication system cable 306 via connections/terminals within the audio jack 302. For example, the intercommunication system cable 306 may have a number of conductors that terminate at the audio jack 302 as the second end of the intercommunication system cable 306.

The clip 304 is configured to connect to a uniform or other item of the respective crew member and thereby secure the second end of the intercommunication system cable to the crew member.

FIG. 4 illustrates an example of an audio jack structure suitable for use with the disclosed subject matter. The audio plug 400 includes a tip 402, a sleeve 404, a tip electrode 406, a sleeve electrode 408, a strain relief clamp 410, a threads 412, and an insulator 414. The tip 402 may be configured to engage a surface within the audio jack and complete a circuit to a microphone and speaker(s) of the crew member headphone/microphone when the audio plug 400 is inserted into or connected to the audio jack. Similarly, the sleeve 404 may also be configured to engage a surface within the audio jack and complete a circuit to a microphone and speaker(s) of the crew member headphone/microphone. For example, the sleeve 404 may provide a ground connection or a shield. The insulator 414 electrically isolates the tip 402 from the sleeve 404. While the example audio plug 400 shows the tip 402 as one signal input there may be other signal inputs/outputs that are separated from one another by additional insulators, such as insulator 414. Examples the additional insulators 414 are shown in other examples containing audio jacks.

Internal to the audio plug 400 are the tip electrode 406, the sleeve electrode 408 and the strain relief clamp 410. The tip electrode 406 is configured to connect to and couple with one of the number of conductors within the intercommunication system cable and the sleeve electrode 408 is operable to connect to and couple with another conductor of the number of conductors within the intercommunication system cable. The strain relief clamp 410 is configured to couple to or connect with a structural feature of the intercommunication system cable to prevent the audio plug 400 from being pulled away from the intercommunication system cable. The threads 412 are used to couple to the audio plug 400 to a housing (not shown) of the crew member's headset (i.e., headphone/microphone) that enables the user to remove and insert the audio plug 400 from and into the audio jack.

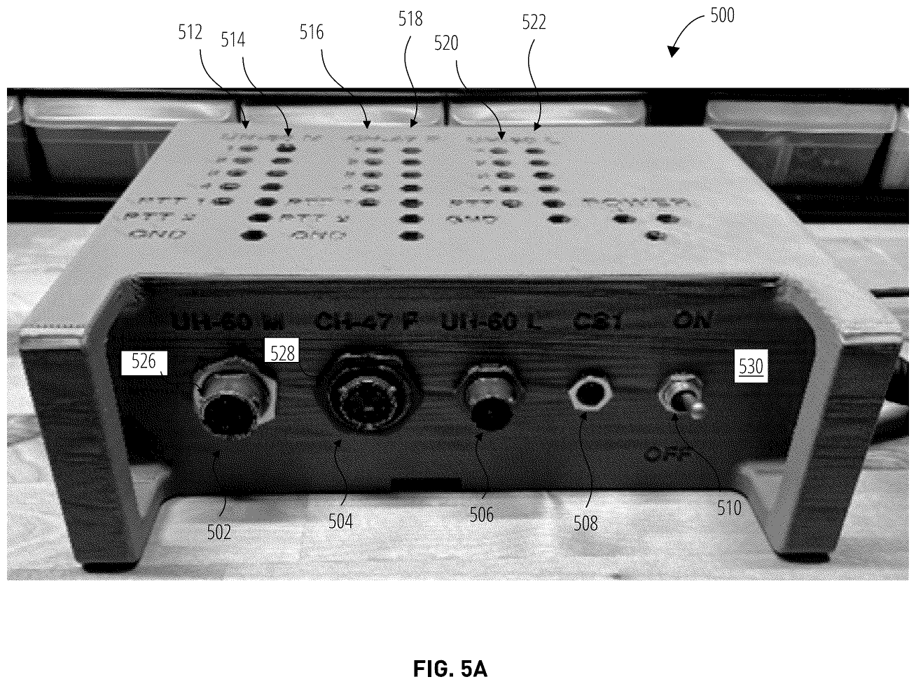

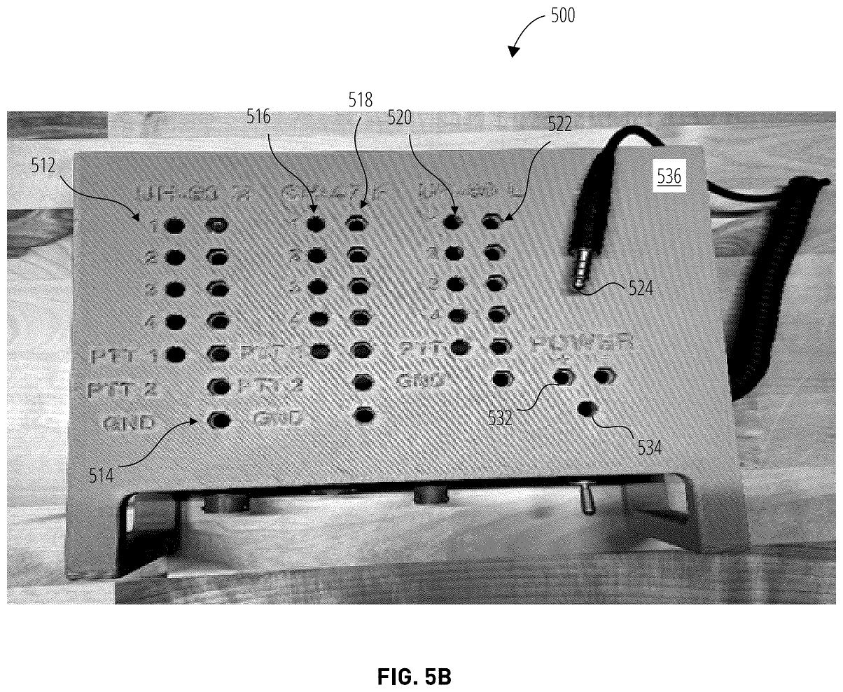

FIG. 5A illustrates an isometric-view of an example of a ruggedized, intercommunication system cable test unit in accordance with the disclosed subject matter. The device is intended to be used by personnel focused on wiring and repair, and should be both understandable and repairable by these people. Ruggedness, reliability, light weight, and functionality are all key.

The ruggedized, intercommunication system cable test unit 500 includes a first connection point 502, a second connection point 504, a third connection point 506, a fourth connection point 508, an on/off power switch 510, indicator lights (first connection point) 512, test points (first connection point) 514, indicator lights (second connection point) 516, test points (second connection point) 518, indicator lights (third connection point) 520, and test points (third connection point) 522. The one or more connection points 502, 504, 506 and 508 are coupled to the end-to-end test circuitry of a ruggedized, intercommunication system cable test unit. The portion of the one or more connection points 502, 504, 506 and 508 shown in FIG. 5A is operable to couple with military-specified communication cable connectors of an intercommunication system cable. Each of the one or more connection points includes a respective input configured to receive a respective pin of a predetermined military-specified communication cable connector configured to connect to a specific one of the connection points 502, 504, 506, or 508. For example, the inputs enable connection of the intercommunication system cable to the ruggedized, intercommunication system cable test unit. In addition, each respective pin is specific to a military-specified communication cable connector used in a specific military aircraft. the one or more connection points, includes a first connection point having a helicopter-specific connector; and an audio jack of a headset including a signal path for at least one audio speaker and another signal path for a microphone.

In FIG. 5A, the view of the first connection point 502, second connection point 504, third connection point 506 and fourth connection point 508. The first connection point 502 is configured to couple to a first end connector, such as 200 of an intercommunication system cable specifically for a UH-60 H aircraft. The second connection point 504 is configured to couple to a first end connector, such as 200 of an intercommunication system cable specifically for a CH-47 aircraft. The third connection point 506 configured to couple to a first end connector, such as 200 of an intercommunication system cable specifically for a UH-60 L aircraft. The fourth connection point 508 is configured to couple to a first end connector, such as 200 of an intercommunication system cable specifically for a CB-1.

The front 530 of the ruggedized, intercommunication system cable test unit 500 may also include an ON/OFF power switch 510, which initiates a test cycle once the intercommunication system cable is connected to one of the connection points 502, 504, 506 or 508 and the audio jack (shown in FIG. 5B).

Each of the connection points may have alignment points. For example, the first connection point 502 may have alignment point 526 and alignment point 528 may be used for the second connection point 504. The respective alignment points 526 and 528 may be configured to match respective alignment keys, such as alignment key 206 on the first end connector 200 of the intercommunication system cable.

In addition, the ruggedized, intercommunication system cable test unit 500 may be configured to allow easy removal and replacement of the first connection point 502, second connection point 504, third connection point 506 and fourth connection point 508.

The respective connection points 502, 504, 506 and 508 may be equipped with an outer securing mechanism that may be configured to secure the military-specified communication cable connector to an outer surface of the ruggedized, intercommunication system cable test unit. An example outer securing mechanism may include one or more fastening elements, such as one or more of: a latch, threads, a threaded coupling, a compression latch, or a spring-based latch. The respective fastening elements may be to secure the military-specified communication cable connector to the outer surface of the ruggedized, intercommunication system cable test.

FIG. 5B illustrates a top-view of an example of the ruggedized, intercommunication system cable test unit in accordance with the disclosed subject matter. The top 536 of the ruggedized, intercommunication system cable test unit 500 includes a number of indicator lights, 512, 516, and 520, as well as a number of test points 514, 518 and 522. The test points 514, 518 and 522 may be configured to measure resistance of a portion of the communication cable coupled to the respective pin of the predetermined military-specified communication connector via the respective connection point 502, 504, 506, or 508 to which the intercommunication system cable is connected for testing.

Also shown is audio jack 524 that is configured to connect to the audio plug 400 of FIG. 4 when the intercommunication system cable is being tested. The test points also include test points for the power source (e.g., battery), such as power source test point 534, to confirm sufficient power supply for testing and/or troubleshooting.

In some instances, the end-to-end test circuitry may only test for open circuits within the respective intercommunication system cable. In these instances, the indicator lights (first connection point) 512 provide an indication of open circuits when the predetermined military-specified communication connector of the UH-60 H intercommunication system cable is coupled to first connection point 502.

The power source may also include a power source indicator 532, which may be a light emitting diode (LED) that indicates the health (i.e., voltage and current capacity) of the power source (shown in a later example).

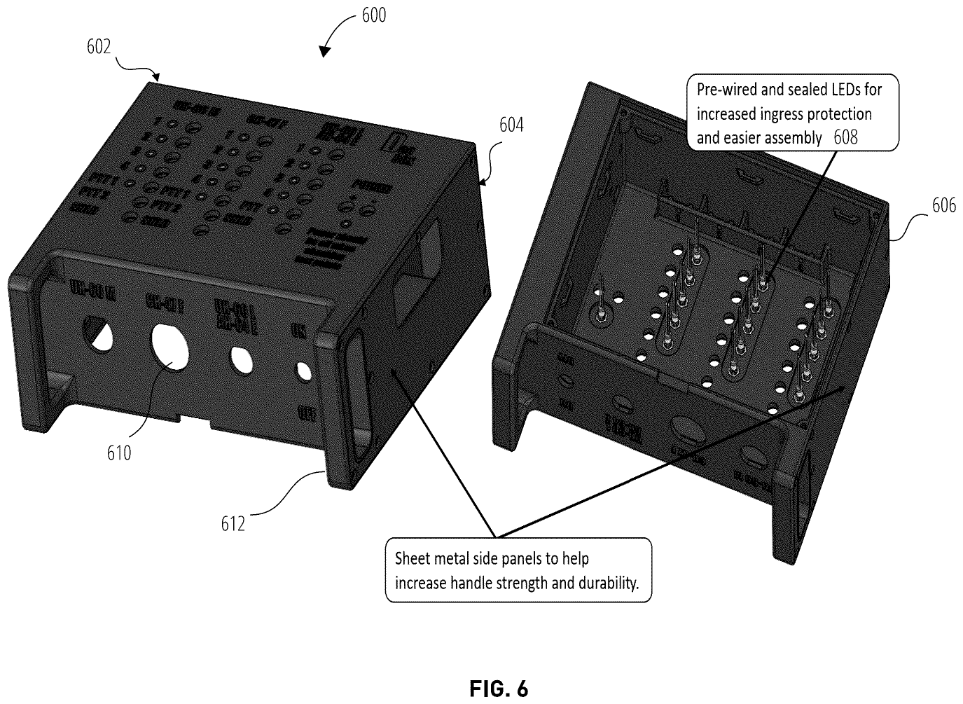

FIG. 6 illustrates exemplary isometric top and internal views of another example of a ruggedized, intercommunication system cable test unit in accordance with the disclosed subject matter.

The housing 602 of the ruggedized, intercommunication system cable test unit 600 may be a unitary or singular structure. The housing 602 constructed as a single unit may be strong, rugged, droppable, and protected from dust, water, and damage with rough handling. The housing 602 may be made according to different manufacturing processes like injection molding and three dimensional (3D) printing.

The choice of housing material may have an effect on the strength and ruggedness of the product, but must also be driven by the final design form factor, manufacturing technology, and of course cost. Choices for housing material include sheet metal, machined metal, printed plastic, cast urethane, compression molded, reinforced reaction injection molding (RRIM), or injection molded. In an example in which the housing 602 is built using 3D printing, materials and processes may be selected to provide a housing 602 having sufficient strength and durability (i.e., “ruggedness”). For example, strength can be improved by choosing appropriate internal fill patterns, infill percentages, and wall thicknesses. For example, due the expected rough handling, the entire ruggedized, intercommunication system cable test unit 600 is expected to be strong, rugged, droppable, and protected from dust, water, and damage associated with rough handling. While the case of build with available three-dimensional printers, such as fused deposition modelling printers, may be an advantage, the housing 602 of the ruggedized, intercommunication system cable test unit 600 can be made much stronger even without design changes with some simple changes to process and material. In a specific example, the strength of the housing 602 may be strengthened by modifying settings of the 3D printer such as an internal fill pattern, an infill percentage, and/or a wall thickness. For example, a hexagonal fill pattern with a 40% infill percentage may provide suitable strength and “ruggedness,” but at the expense of taking longer to print. Alternatively, a material stronger than PLA, such PETG or ABS may be more suitable, while use of a carbon fiber material/printer may provide even greater strength properties.

While a sheet metal housing may provide ruggedness, sheet metal is heavier than the plastics and other materials described herein and may have more issues with reliability due to shorting and sharp edges, particularly when used while in flight or at a forward area. The housing 602 shown in the examples herein may be made by a 3D printing process that may incorporate sheet metal side panels 604 and 606 to increase the strength/durability of the ruggedized, intercommunication system cable test unit 600. The housing 602 may include openings that serve as connection point through holes 610 that enable installation and removal of connection points for aircraft-specific intercommunication system cables. The front of the housing 602 may also include handles 612 that enable the ruggedized, intercommunication system cable test unit 600 to be portable, facilitate connection of the intercommunication system cables for testing, and provide protection to the connections when the cables are connected.

The internal view on the right of FIG. 6 shows an example of prewired watertight LEDs 608 installed which significantly improves the water tightness of the LEDs 608 and reduces assembly time. Alternatively, pre-wired, sealed panel mount LEDs, recessed if needed, may be used to case assembly, and improve ruggedness/durability.

Additional features that may be added to this example of a ruggedized, intercommunication system cable test unit 600 as well as other examples may include one or more features. For example, when repairing an intercommunication system cable using a soldering iron, a clamp/hold down to hold an audio jack end of a communication system connector may be beneficial. In addition, integrated storage, mounting, holding, or other functions/features for meters, test probes, soldering irons, crimps and crimpers, and other tools may also be implemented in the housing 602.

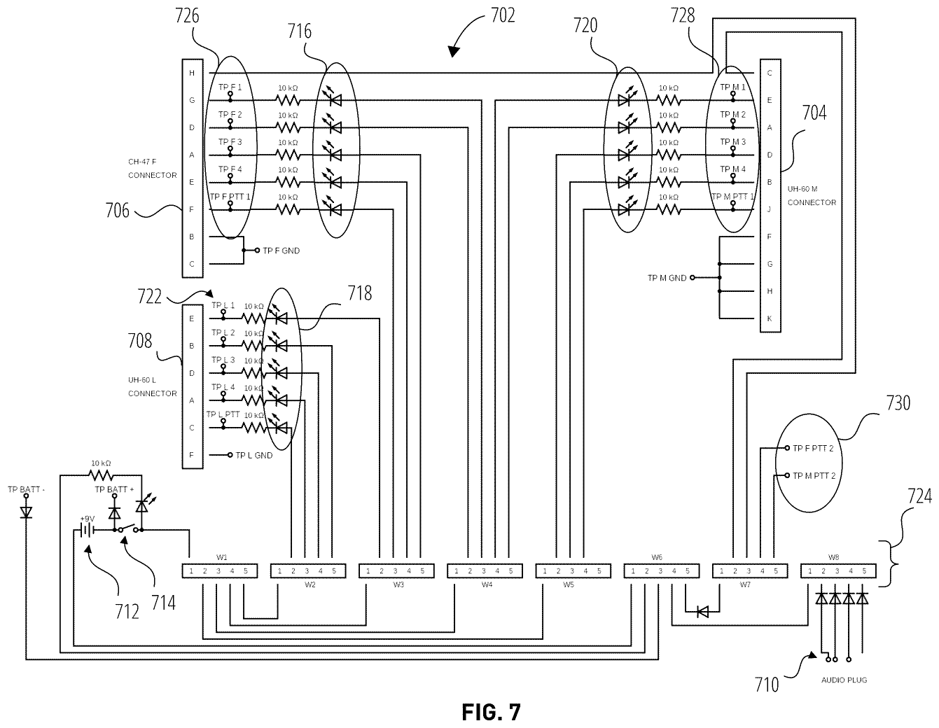

FIG. 7 illustrates an example of a schematic diagram of end-to-end test circuitry according to an embodiment of the disclosed subject matter.

In the example illustrated in FIG. 7, the end-to-end test circuitry 700 may include a first connector 702, a second connector 704, a third connector 706, and an audio plug 708. The first connector 702 may correspond to the first connection point 502 of FIG. 5A, the second connector 704 may correspond to the second connection point 504 of FIG. 5A, and the third connector 706 may correspond to the third connection point 506 also of FIG. 5A.

When configured within the ruggedized, intercommunication system cable test unit, the connectors 702, 704 and 706 may also be described as communication system connectors that are disposed in a housing of the ruggedized, intercommunication system cable test unit. Each communication system connector 702, 704 and 706 may include one or more inputs configured to link with the plurality of pins of the intercommunication system cable for a specific type of military aircraft, and be coupled to the end-to-end test circuitry 700. And when the end of the intercommunication system cable is secured to a respective communication system connector 702, 704, or 706, the one or more inputs are part of a respective test signal pathway to the audio connection end (i.e., the audio plug 708) of the intercommunication system cable.

The end-to-end test circuitry 700 may also include a power source 710, an on/off switch 712, indicators 714, indicators 716, indicators 718, test points 720, terminal blocks 722, a test points 724, and a test points 726.

The terminal blocks 722 may be points on a circuit board that couple the respective connection points, power source 710 and other features of the end-to-end test circuitry 700 together to implement the ruggedized, intercommunication system cable test unit.

The indicators 714, 716 and 718 may correspond to indicator lights (first connection point) 512 of FIG. 5A, indicator lights (second connection point) 516 of FIG. 5A, and indicator lights (third connection point) 520 of FIG. 5A, respectively.

A test cycle may be initiated when a first end connector of an intercommunication system cable is coupled to the respective connection point 702, 704, or 706 and a second end (e.g., audio jack) of the intercommunication system cable is coupled to the audio plug 708.

The test points 720, 724 and 726 enable a multimeter to be used to make specific measurements at the respective different points in the circuitry of the end-to-end test circuitry 700.

The end-to-end test circuitry 700 may be configured for open circuit, short circuit, and/or resistance testing of the test signal pathways of the respective intercommunication system cables.

In a resistance test example, a multimeter may be coupled at respective test points may be operable to measure an amount of resistance (in ohms) in one or more cables forming the intercommunication system cable. Depending upon the measured resistance value, the intercommunication system cable may be determined to be operational or degraded, in need of repair. Similarly, in a short circuit test example, a multimeter may be coupled at respective test points, such as between wires of a cable, may be operable to measure an amount of resistance (in ohms) in one or more cables forming the intercommunication system cable. However, when there is a short circuit between cables, the amount of resistance (in ohms) between the respective cables may be substantially zero. Alternatively, if no short circuit is present, the amount of resistance is expected to be large (tens or thousands of Kohms).

In an open circuit test example, the end-to-end test circuitry 700 may be configured to test integrity of an intercommunication system cable when the intercommunication system cable is coupled to the audio jack and the communication system connector. The end-to-end test circuitry 700 may detect whether an open circuit is present in the intercommunication system cable; and in response to detecting presence of the open circuit, produce an output via indicators 714, 716, or 718 indicating the presence of the open circuit.

The exemplary end-to-end test circuitry 700 indicates conductivity of the respective test signal pathways using circuits that include, for example, an LED, a resistor, such as a 10K ohm resistor, and a 9 volt (V) battery. For example, the magnitude of the electrical current is about (9−2.5−0.6)/10K=0.59 milliamperes (mA), which may cause the LED to generate light that may be dim but visible. This is based on the battery voltage (9 V), LED drop voltage (2.5 V), and diode voltage drop (0.6 V) of the audio jack inserted in the audio plug 708. In some examples, the 10K resistor may be lowered to increase brightness, however, the lower resistance value of the resistor may be insufficient to indicate higher resistance in the cable/connection, which can be within the range of approximately 10-500 Ohms, or the like. While specific voltages and resistance values are described, it is envisioned that other values may be utilized to accomplish a similar test result.

Modifications may include adding additional test points for the direct measurement of resistance using a multimeter. In earlier embodiments, for example, the test points are on the top of the box and properly located on the circular connector end, but there are not test points shown before the diodes on the audio plug input end. However, by adding resistance test points 728 prior to the diodes on the audio plug input end may allow a technician to use a multimeter to accurately measure resistance.

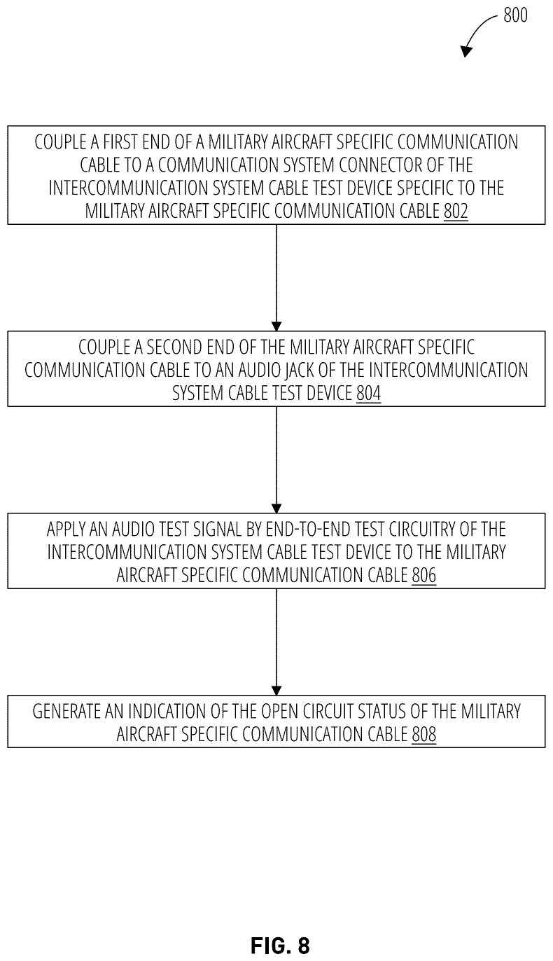

FIG. 8 illustrates an exemplary method of using the ruggedized, intercommunication system cable test unit in accordance with at least one embodiment of the disclosed subject matter.

In block 802 of the end-to-end test process 800, a first end of a military aircraft specific communication cable may be coupled to a communication system connector of the ruggedized, intercommunication system cable test unit specific to the military aircraft specific communication cable. For example, a UH-60 M intercommunication system cable may be coupled to a predetermined military-specified communication connector corresponding to the UH-60 M helicopter communication system.

In block 804 of the end-to-end test process 800, a second end of the military aircraft specific communication cable may be coupled to an audio jack of the ruggedized, intercommunication system cable test unit. For example, the audio jack of the ruggedized, intercommunication system cable test unit may be coupled to the second end (i.e., the audio plug) of UH-60 M intercommunication system cable.

Once the intercommunication system cable has been connected to cable's corresponding connection point and the audio jack, the end-to-end test process 800, at 806, may apply (automatically or via a selection switch) a test signal via the end-to-end test circuitry of the intercommunication system cable test device to the military aircraft specific communication cable. The test signal may be a signal representative of a sound, a variable voltage and/or variable frequency signal, or may be a constant DC signal.

In an example, when applying the test signal by the end-to-end circuitry, the end-to-end test process 800 may include in response to selection of a test device setting corresponding to an aircraft type of the military aircraft specific communication cable, setting a switch configuration coupling respective inputs of the communication system connector to which the first end of the military aircraft specific cable is coupled, and switching the application of the audio test signal among the respective inputs of the communication system connector.

In block 808, the end-to-end test process 800, in response to the applied audio test signal, generates an indication of the open circuit status of the military aircraft specific communication cable. In this example, the end-to-end test circuitry may only detect open circuits. The end-to-end test circuitry of this example may not be configured to detect shorts or resistive/intermittent connections (i.e., not completely open circuits). In addition, or alternatively, the end-to-end test circuitry may be configured to indicate the location of a failure/break.

In an example, when generating the indication of the open circuit status of the military aircraft specific communication cable, the end-to-end test process 800 may include illuminating a visual indication of the open circuit status, emitting an audio indication of the open circuit status, or both. Alternatively, or in addition, the end-to-end test process 800 may cause a visual indication of the open circuit status to be generated. In the example, the visual indication includes a respective light emitting diode of a plurality of light emitting diodes being numbered to correspond to a distinct signal path through the military aircraft specific communication cable that is faulty. Of course, other visual indications may be generated. For example, holding the visual indication of the open circuit status of the distinct signal path until the ruggedized, intercommunication system cable test unit is reset.

Since the intercommunication system cables are a specific type of audio cables, there are signal quality issues as well. In an example, the end-to-end test circuitry may be configured to evaluate audio signal quality. For example, an audio signal may be applied as the audio test signal by the end-to-end test circuitry during testing, and different circuitry may be operable to reproduce the audio signal as sound with a speaker, as well as evaluate the sound quality by measuring the total harmonic distortion (THD), or the like. For example, the generated indication of the open circuit status of the military specific communication cable may be an audible signal representative of the audio test signal produced via an audio device, such as a speaker, buzzer, vibration device, or the like.

Although the example routine of FIG. 8 depicts a particular sequence of operations, the sequence may be altered without departing from the scope of the present disclosure. For example, some of the operations depicted may be performed in parallel or in a different sequence that does not materially affect the function of the routine. In other examples, different components of an example device or system that implements the routine may perform functions at substantially the same time or in a specific sequence.

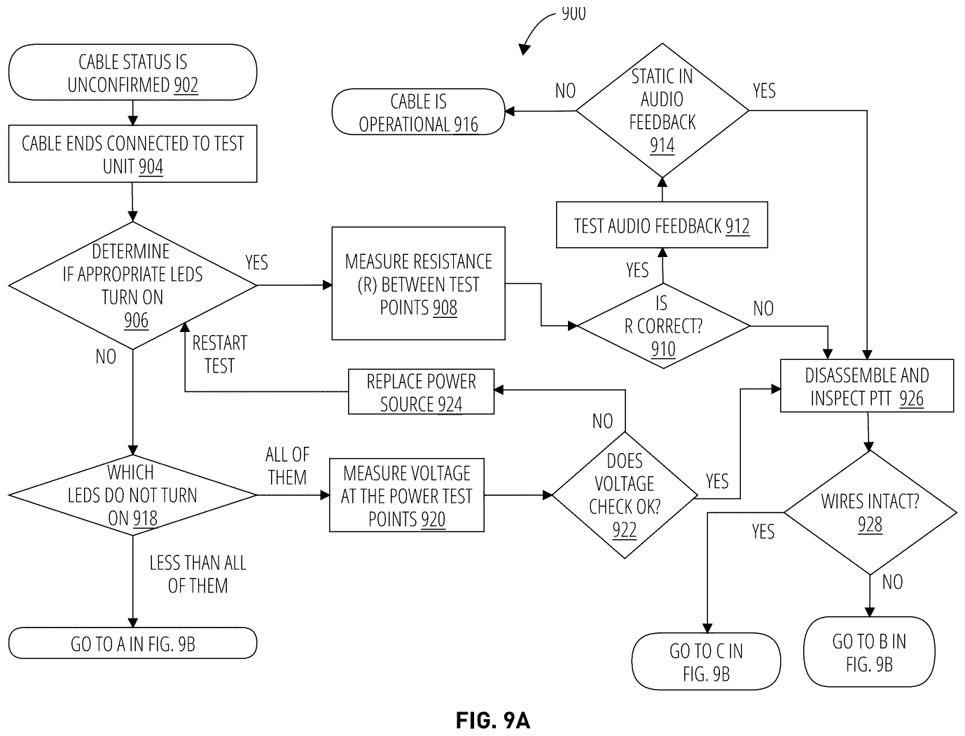

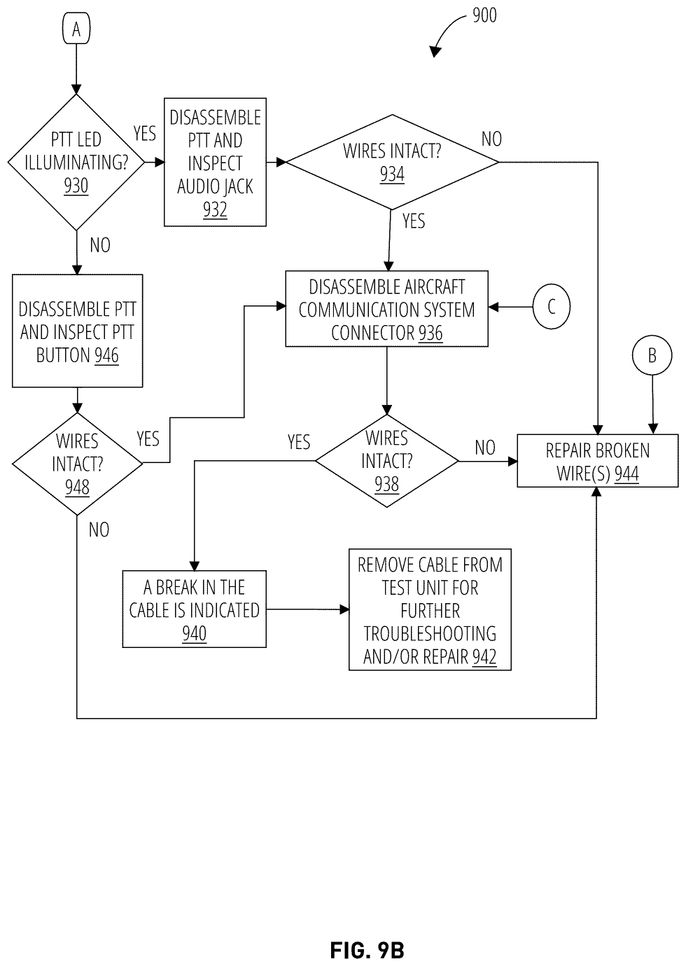

FIGS. 9A and 9B illustrate another exemplary method of using at least one embodiment of the ruggedized, intercommunication system cable test unit as described herein.

Although the example method illustrated in FIGS. 9A and 9B depicts a particular sequence of operations, the sequence may be altered without departing from the scope of the present disclosure. For example, some of the operations depicted may be performed in parallel or in a different sequence that does not materially affect the function of the routine. In other examples, different components of an example device or system that implements the routine may perform functions at substantially the same time or in a specific sequence.

At block 902, it may be determined an intercommunication system cable may have an unconfirmed status. For example, the status of the intercommunication system cable may be either “operational” (meaning it is intact and can be used in flight operations) or “needs repair” and execution of the method 900 confirms the status of the intercommunication system cable. Intercommunication system cables with unconfirmed status are in need of testing. For example, the intercommunication system cables may have labels or tags indicating the unconfirmed status, or may be placed in a location for cables having an unconfirmed status.

According to some examples, the intercommunication system cable ends (i.e., the predetermined military-specified communication connector and an audio plug, such as 400 of FIG. 4) may be connected to test unit at block 904.

As discussed with reference to earlier examples, the operational test method 900 includes, at block 906, determining whether the appropriate LEDs turn on. For example, the LEDs that indicate that the power source is turned on may illuminate (i.e., turn on). In the case that the intercommunication system cable connected to the ruggedized, intercommunication system cable test unit is operational (i.e., fully functional) all of the LEDs that correspond to the specific intercommunication system cable being tested will illuminate. As such, the determination at decision block 906 is “Yes.” In response to the YES at decision block 906, the operational test method 900 proceeds to block 908. At block 908, the resistance (R) (in ohms) between test points in the top of the ruggedized, intercommunication system cable test unit may be measured. For example, the resistance (R) may be measured between the test points (shown in other examples) using a digital multi-meter or the like. A benefit of the test points is that they resistance is measured from the same point on the intercommunication system cable and there need not be much concern for an appropriate connection between the probe of the digital multi-meter. A determination is made at decision block 910 whether the measured resistance (R) at all of the test points is within an acceptable tolerance of a reference resistance (e.g., 2-5% of the reference, +20-50 milliohms, or the like) for the specific intercommunication system cable being tested. If the determination at 910 is “Yes,” the resistance (R) at the respective test points is within tolerances for the reference resistance of the respective wires of the intercommunication system cable being tested. The intercommunication system cable is then subjected to an audio test.

At block 912, the operational test method 900 causes an audio signal (e.g., via a tone generator or the like) to be generated. At decision block 914, it is determined whether static is present in the audio feedback that is output from the ruggedized, intercommunication system cable test unit via an output device, such as a speaker or the like. Alternatively, as discussed in other examples, the end-to-end test circuitry may include circuitry to test audio fidelity, such as THD or the like, and an indication of the THD may be presented. In response to “No” static being present in the audio feedback, at decision block 914, the cable is designated at 916 as “operational.”

Returning to decision block 910, if the determination is that the resistance is not correct (i.e., the determination is “No”), the operational test method 900 proceeds to block 926. Block 926 also is responsive to a decision at decision block 922. However, to arrive at decision block 922, a “No” determination at decision block 906 has to be determined.

In response to the “No” determination at decision block 906, the operational test method 900 proceeds to decision block 918. At decision block 918, a determination between whether “All” of the LEDs turn on or “less than all” turn on. If the determination at decision block 918 is all of the LEDs turn on, the operational test method 900 proceeds to block 920. Alternatively, if the determination at decision block 918 is less than all of the LEDs turn on, the operational test method 900 proceeds to A in FIG. 9B.

At 920, the voltage of the power source is measured at the power source test points. At decision block 922, a determination is made whether the measured voltage is within tolerance (e.g., +2-5% or the like) of a reference voltage (e.g., 9 volts), if the determination is “No,” the measured voltage is not within tolerance of the reference voltage, the operational test method 900 proceeds to block 924. At block 924, the power source may be replaced. For example, an indication (e.g., an audible indicator and/or visual indicator) may be presented on the ruggedized, intercommunication system cable test unit. Once the power source is replaced at block 924, the operational test method 900 returns to decision block 906 to restart testing of the intercommunication system cable under test.

However, if the measured voltage is within tolerance (e.g., +2-5%, +0.25-1.0 volts, or the like) of the reference voltage (e.g., 9 volts), the determination at decision block 922 is “Yes,” the operational test method 900 proceeds to block 926.

At block 926, in response to either the measured resistance not being correct (i.e., “No,” not within tolerance of the reference resistance) from decision block 910 or the power source voltage being within tolerance of the reference voltage at decision block 922, the operational test method 900 recommends disassembling the push-to-talk assembly, such as that shown in FIG. 3, and inspecting the connections and wires. If the determination at 928 is “YES,” the wires and connections are intact, the operational test method 900 proceeds to C in FIG. 9B. Alternatively, if the determination at 928 is “No,” the wires and connections are not intact, the operational test method 900 proceeds to B in FIG. 9B.

At point A in FIG. 9B, the operational test method 900 proceeds to 930 determine whether the push-to-talk LED is illuminating, which can indicate a fault with the push-to-talk button or PTT button wiring connections within the PPT assembly. If the response is “NO,” the push-to-talk LED is not illuminating, the operational test method 900 proceeds to 946 which instructs disassemble and inspect the PTT button. Alternatively, if the response is “YES” at 930, the push-to-talk LED is illuminating, the operational test method 900 proceeds to 932, which instructs disassemble PTT and inspect the audio jack (i.e., the part of the intercommunication system cable) that the audio plug is inserted.

After the PPT wires and PTT button have been inspected, a determination at 946 is made whether the wires and connections are intact. If “YES,” the operational test method 900 proceeds to 936, where the communication system connector at the other end of the intercommunication system cable is disassembled and inspected. Similarly, if after the PPT assembly is disassembled and the audio jack is inspected at 932, a determination at 934 is made whether the wires and connections are intact. If “YES,” the operational test method 900 proceeds to 936, where the communication system connector at the other end of the intercommunication system cable is disassembled and inspected. Block 936 (i.e., Point C) is the step performed in FIG. 9B after the “YES, the wires and connections are intact” determination at 928 of FIG. 9A.

After disassembling the aircraft communication system connector at 936, a determination has to be made whether the wires and connections are intact at decision block 938. A determination that the wires and/or connections are intact, indicates that there is a break or fault in the intercommunication system cable that may require more extensive testing. As a result, the intercommunication system cable is removed from the test unit for further troubleshooting and/or repair (942).

Returning to the wires intact decision block 948, if the determination is “No,” the wires and/or connections are not intact, the operational test method 900 proceeds to block 944, which recommends repairing any wires or connections (including communication system connectors and/or audio plugs) that are broken and need to be repaired.

Similarly, returning to the wire is intact decision block 938, if the determination is “No,” the wires and/or connections are not intact, the operational test method 900 proceeds to block 944, which instructs that the wires or connections are broken and need to be repaired.

Block 944 is also the point (i.e., Point B) where operational test method 900 proceeds when the output of decision block 928 (i.e., “No,” the wires are not intact), and the recommendation is to repair the broken wires and/or connections (or replace the communication system connector, if damaged, or the audio plug, if damaged).

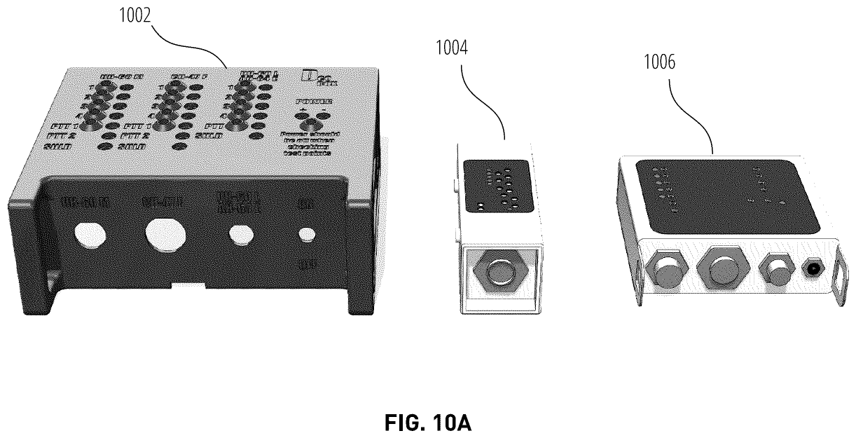

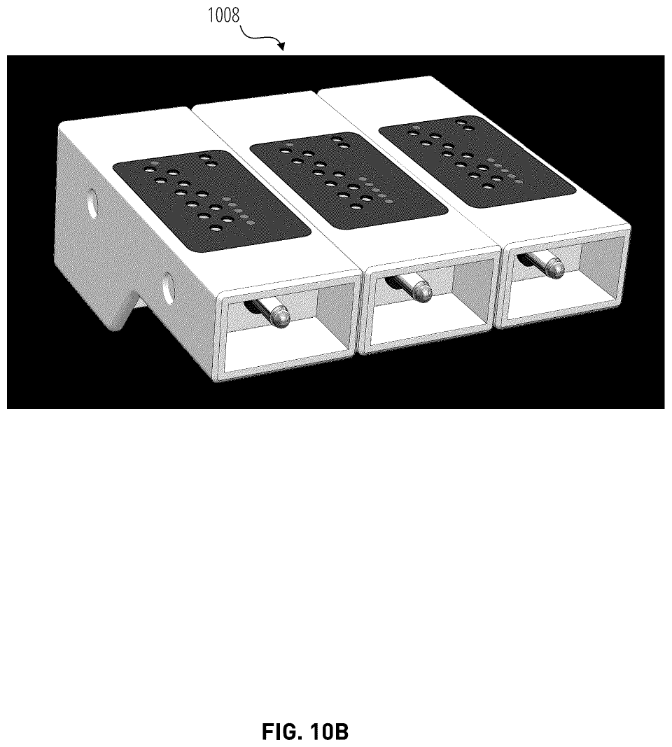

FIG. 10A illustrates alternative exemplary housings for the ruggedized, intercommunication system cable test unit according to different aspects of the disclosed subject matter.

Thus far, the described examples have referred to a ruggedized, intercommunication system cable test unit, such as multi-cable test unit 1002, that is configured to test multiple different cables. However, it is also envisioned that cable specific test units, such as single cable test unit 1004 may be easily produced to allow crew members to quickly evaluate intercommunication system cables either onboard the respective aircraft or when a squadron of the same aircraft are deployed to a forward operating base that may not have well-equipped repair facilities or may need to bring a minimum amount of equipment.

For example, the single cable test unit 1004 may only have a predetermined military-specified communication connector that is specific to the military aircraft and the intercommunication system cable used by that military aircraft. While not shown the audio jack may be connected at the rear of the single cable test unit 1004.

It is also envisioned that a more compact, multi-cable test unit 1006 may also be produced. Space savings may be provided by less shock-resistant, less watertight LEDs, and the like.

FIG. 10B illustrates yet another exemplary housing for the ruggedized, intercommunication system cable test unit according to different aspects of the disclosed subject matter.

In another example, the small, light, hand-held design has advantages, such as where three of the single cable test units 1004 can be fitted together (e.g., snapped together) for modularity. The single cable test unit 1004 may be further configured to be ganged together via the use of an attachment feature, such as a pin and groove configuration, latch and hook material, a clamping arrangement, or the like. For example, as shown in FIG. 10B, the single cable test unit 1004 may have an alternate configuration where different types of testers having different predetermined military-specified communication connectors can be ganged together as ganged, single test units 1008 with an attachment feature. For example, one of the three illustrated single cable test units may be for a UH-60 M aircraft, another for the CH-47 aircraft, and yet a third for the UH-60 L aircraft. The form factor of the ganged, single test units 1008 may be no larger, for example, than a digital voltage meter.

In an example, each single cable test unit 1004 of the ganged, single test units 1008 may have its own battery, and may be configured to be usable independently of the other single test units of the ganged, single test units 1008.

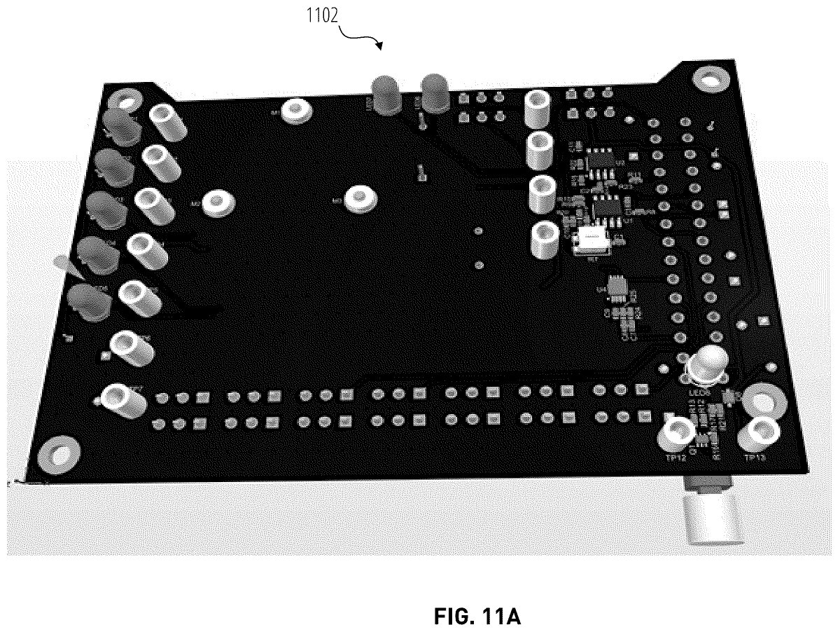

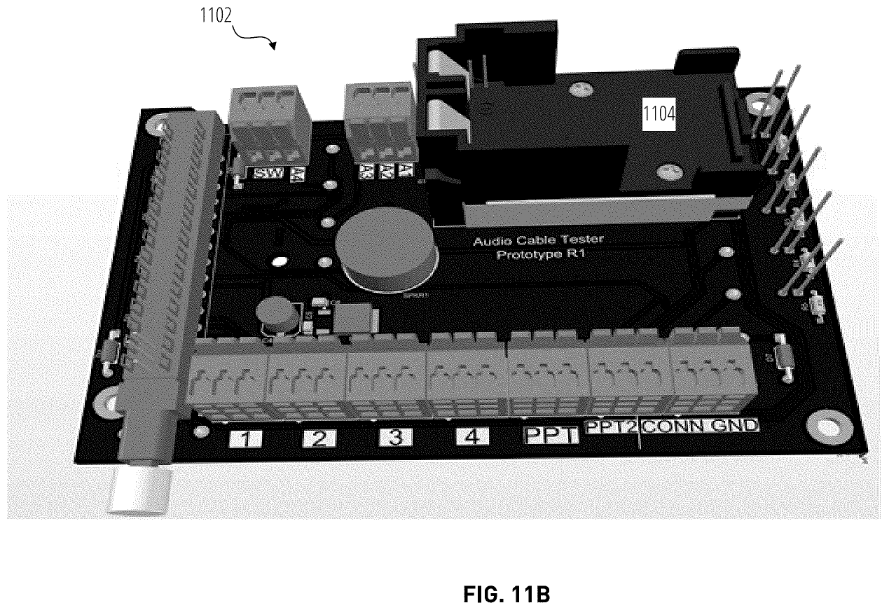

FIG. 11A illustrates a top-view of an exemplary circuit board for implementing aspects of the disclosed subject matter in accordance with one embodiment.

The end-to-end test circuitry example illustrated in FIG. 7 may be implemented on a circuit board in various configurations. One of those configurations is a through-hole version as illustrated in FIG. 10A. In the end-to-end test circuitry (through hole) 1102, the top of the printed circuit board may have LED indicators, test points, and a switch. In addition, here are 4 mounting holes suitable for #6 or M3.5 hardware, and the test points are 2 millimeter tip jacks. The board size may be 4.5 inches by 3.5 inches. Of course, other boards of different sizes may be used. In addition, multiple boards may also be used.

FIG. 11B illustrates a bottom-view of the exemplary circuit board of FIG. 11A for implementing aspects of the disclosed subject matter in accordance with one embodiment.

The bottom of the board 1102 contains a battery holder 1104, diodes, resistors, and wire terminal connectors for all 3 connector types, (e.g., a connector for UH-60 M, a connector for CH-47, and a connecter of UH-60 L (all of which may be wired in parallel in this example). Due to the connectors being wired in parallel, the end-to-end test circuitry is operable to only be used with one cable at a time. However, the end-to-end test circuitry may be configured to test multiple cables at a time by duplicating all of the LEDs for the separate connectors. The silk screening of the circuit traces on the bottom of the circuit board may include labels for all connectors for easy assembly and repair if needed. Of course, additional configurations are also envisioned.

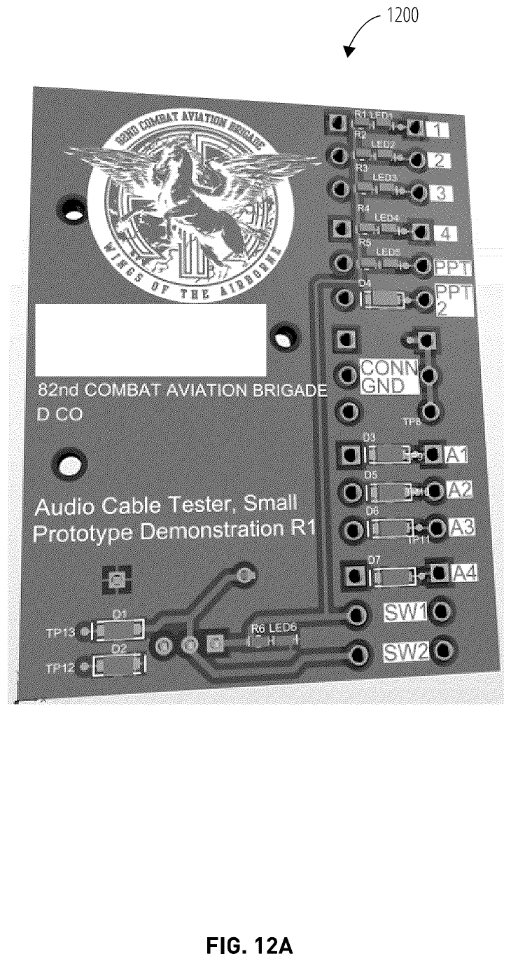

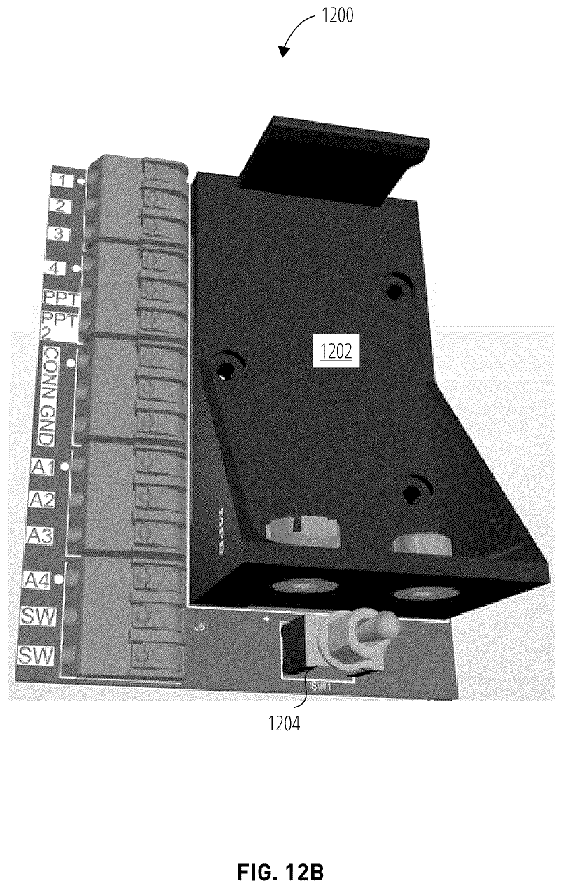

FIG. 12A illustrates a top-view of another exemplary circuit board for implementing aspects of the disclosed subject matter in accordance with one embodiment.

The mixed surface mount circuit board implementation 1200 may be formed by using surface mount components for the LEDs, resistors, and diodes. As a result, a smaller and tighter design becomes easy, limited only by the size of the battery holder and connectors. For this example, implementation, the redundant terminal connections for the different types of connection points may be eliminated, so the mixed surface mount circuit board implementation 1200 only directly supports a single connector, but 2 or more communication cable test units may be daisy-chained or fastened together externally as in the ganged, single test units 1008 of FIG. 10B. The mixed surface mount circuit board implementation 1200 board may have dimensions slightly smaller than approximately 2 inches×2.5 inches, less than one-third the area of the through-hole version described above with reference to FIG. 10A above.

As shown in FIG. 12A, the top of the mixed surface mount circuit board implementation 1200 board has the LEDs, diodes, and resistors, as well as all of the traces. The dedicated pin jack test points of the previously discussed embodiments have been eliminated in the mixed surface mount circuit board implementation 1200. In this example, the pin jack test points may be replaced in the mixed surface mount circuit board implementation 1200 with surface mount pads and/or the wire connector solder pins available as test points through openings in the top of the housing (such as housing 602), or may be provided as molded-in-pogo pin test points.

FIG. 12B illustrates a bottom-view of the other exemplary circuit board of FIG. 12A for implementing aspects of the disclosed subject matter in accordance with one embodiment.

This board does not have any mounting provisions other than the 3 screw holes through the battery holder 1202, but due to the small size these are unlikely to interfere with other components (e.g., traces, diodes, test points, or LEDs). The battery holder 1202 and wire connectors remain the same through-hole components used in the other design. Also included in this embodiment is an on/off switch 1204 that may be configured to protrude through the housing of the ruggedized, intercommunication system cable test unit for access. For example, the communication cable test unit may be configured with a small hand-held box with a circular connector at one end and the audio plug at the other, such as compact, multi-cable test unit 1006 of FIG. 10A, perhaps, for example, recessing both the connection point for a first end of the intercommunication system cable and the audio plug for protection.

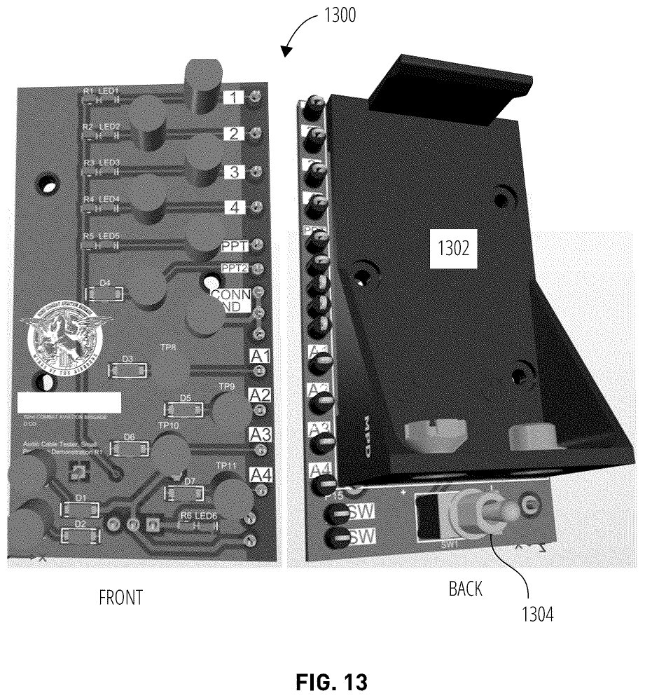

FIG. 13 illustrates a front-view and a back-view of yet another exemplary circuit board for implementing aspects of the disclosed subject matter in accordance with one embodiment.

By eliminating the large through-hole wire connectors of an earlier example, either replacing them with surface mount versions, higher density options, or directly soldering the connector wires to the printed circuit board (PCB) containing the end-to-end test circuitry, a single cable design, such as that of single cable test unit 1004 of FIG. 10A easily fits in a board matching the outline of the battery holder 1302. In the end-to-end test circuitry example of FIG. 13, the small surface mount option of the end-to-end test circuitry 1300 enables a small, light, hand-held design to be implemented as the single cable test unit 1004.

The printed circuit board in this example implementation of the end-to-end test circuitry 1300 may be approximately 1.4 inches by 2.5 inches, and assumes that the connector wires are soldered to the provided holes, or attached with some other small wire termination connector to the provided through hole pads. The test points may be configured to use tip jack test points for standard meter leads, surface mount LEDs, resistors, and diodes. The housing, such as those shown in other examples, may be configured to incorporate light pipes for the LEDs to eliminate bleeding, or a lensed LED could be used. Because the example of FIG. 13 uses through hole soldered parts on both sides of the board, the battery holder 1302 may not sit flush with the board, so either the leads would need to be trimmed, or a spacer like double-sided VHB tape may be used to mount and space the battery holder 1302 to the back of the board. Also, shown is an on/off switch 1304 that may be accessible through the housing, such as housing 602.

The end-to-end test circuitry 1300 is aesthetically attractive and likely to be strong and rugged, primarily because of the small size and weight. It may be too small, but the housing (shown in other examples) may be configured to add size, or may be made larger.

When deciding which of the forgoing implementations to use it may be beneficial to consider: Ruggedness can be achieved with strong, stiff, and heavy, or with light and flexible; small and light is beneficial for airborne applications, such as those where the ruggedized, intercommunication system cable test unit is deployed with the aircraft; light weight reinforced material (fiberglass, carbon fiber fill) may provide structural rigidity and ruggedness; and shock absorbing armor, like the TPE, silicone, low durometer urethane, or other rubber like materials may also increase ruggedness.

For extreme environments and the highest degree of ruggedness, but at the expense of serviceability, the end-to-end test circuitry may be partially (or fully) potted except for the circular connector(s) and the battery of course. Potting may be beneficial for a single connector type, such as single cable test unit 1004 of FIG. 10A, which is also most likely to be selected as an aircraft deployable implementation.

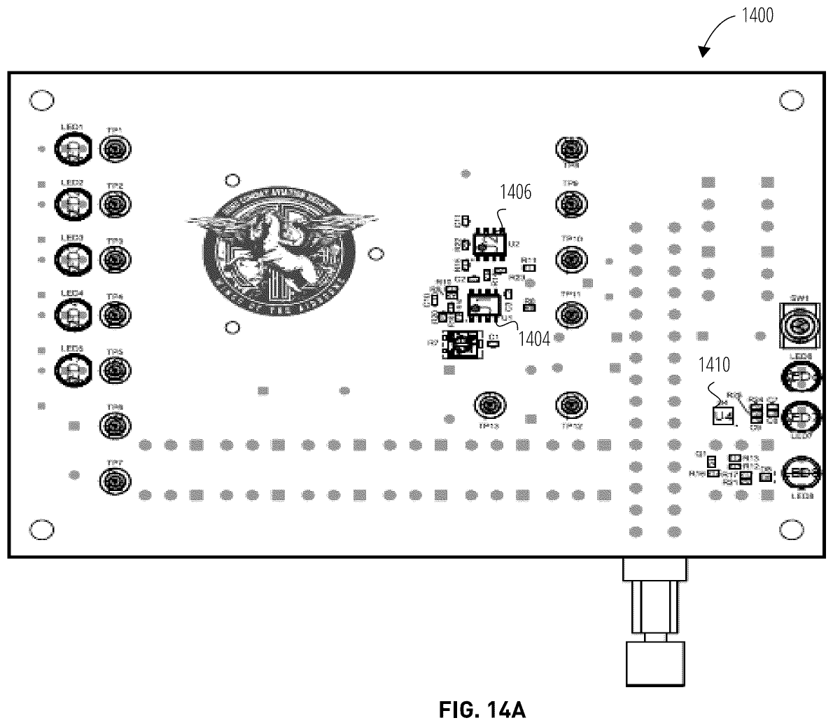

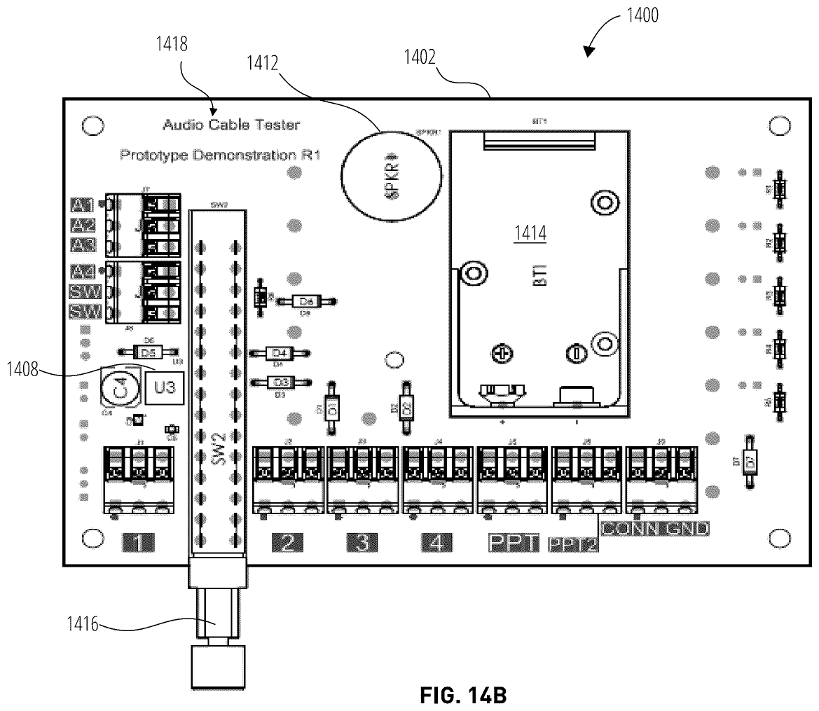

FIG. 14A illustrates a top-view of a further exemplary circuit board for implementing aspects of the disclosed subject matter in accordance with one embodiment.

Mechanical and assembly considerations for the exemplary end-to-end test circuitry 1400 may include the use of surface mount and/or through hole technology for the printed circuit board (PCB) 1402.

For example, through the use of both surface mount technology and through hole techniques, the end-to-end test circuitry 1400 may include operational amplifier 1404, operational amplifier 1406, a voltage regulator 1408, and power amplifier 1410 as well as other components, such as diodes, resistors, and capacitors. The power amplifier 1410 may be an audio power amplifier mounted on a top side of the PCB 1402 for driving a speaker (shown in FIG. 14B) mounted on the bottom side of the PCB 1402.

The use of through-hole parts provides high strength so components such as connectors and battery holders may be securely mounted and remain durable, while surface mounting may be used for the small, light, active and passive components.

The end-to-end circuitry 1400, may include passive components in the PCB, such as wire terminal connectors to interface with the connectors and audio cable. Other connections, such as those to the battery, the LEDs, and the like, as well as those to the switch may be either PCB mounted or wired.

Other design considerations for the PCB are dependent on the final design choices and packaging. Boards can be very rugged, built thicker than the standard 0.062 inch for added strength and rigidity if needed, have additional mounting points, include shock mounting, etc. While there are added costs for double-sided assembly, the volume on this design is so low that the savings would be minimal, and the advantage of smaller size is likely more important.

Another advantage of PCB designs may include using silk screening on the PCB for documentation and debug instructions. For example, the silkscreen documentation 1418 may be configured to clearly label each connection and function, as well as including any other text or graphical information that might be helpful to the technician, the end-to-end circuitry may be easier to understand, troubleshoot, and repair.

Additional features that may be incorporated into the smallest version of the end-to-end test circuitry may include a microcontroller configured to implement audio path testing and control of a small speaker or other sound generating device.

FIG. 14B illustrates a bottom-view of the further exemplary circuit board of FIG. 14A for implementing aspects of the disclosed subject matter in accordance with one embodiment.

The bottom-view shows the connection of the various components to the PCB. For example, the battery holder 1414 and a speaker 1412 are coupled to the bottom side of the PCB. Power may be supplied the power source, such as a 9 volt battery or the like, held in the battery holder 1414. The speaker 1412 may be an audio indicator coupled to the end-to-end test circuitry, such as end-to-end test circuitry 700. The audio indicator provides an indication of the open circuit, when present, for a respective test signal pathway by producing an audio output. The mode selection switch 1416 may transition connections of the switch to select the type of intercommunication system cable that is being tested by the end-to-end test circuitry.

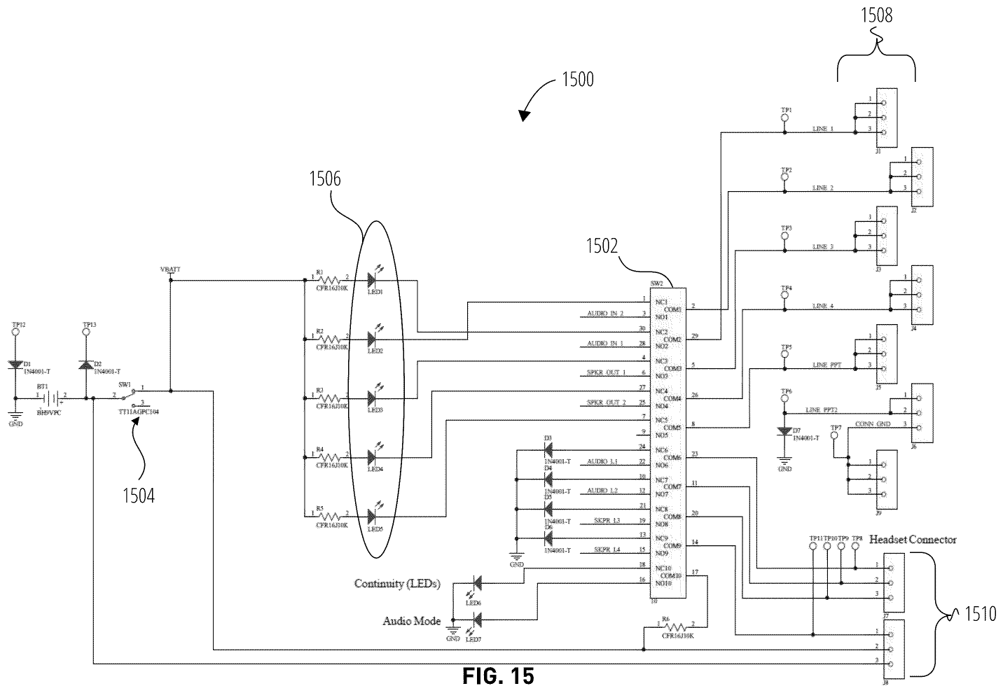

FIG. 15 illustrates an example of another schematic diagram of end-to-end test circuitry according to an embodiment of the disclosed subject matter.

The exemplary end-to-end test circuitry 1500 includes a selector switch 1502, an on/off switch 1504, an indicator LEDs 1506, a connector terminal blocks 1508, and an audio jack terminal blocks 1510.

This embodiment includes switches and circuits in the end-to-end test circuitry 1500 may include a specific number of connections. For example, selector switch 1502 may be implemented as one or more switches, such as rotary switches, which may be operable to select function and line selection(s).

Alternatively, a number of leads and test points (as shown in earlier examples of the end-to-end test circuitry 1500, may replace the selector switch 1502. The end-to-end test circuitry 1500 may also incorporate options to determine short circuit, open circuit, audio path, fault location, and intermittent test mode circuits as well as test points and indicator LEDs 1506.

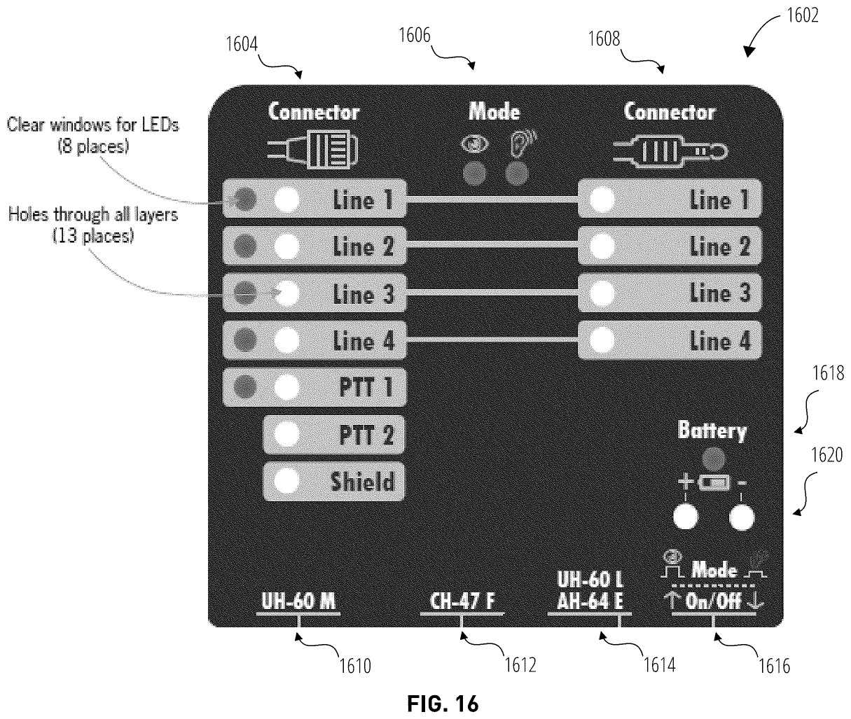

FIG. 16 illustrates a high level example of end-to-end test circuitry according to the disclosed subject matter. In the example, the end-to-end test circuitry 1602 may include connector circuits 1604, a mode indicator 1606, audio jack circuits 1608, a first aircraft ICS connector 1610, a second aircraft ICS connector 1612, a third aircraft ICS connector 1614, an on/off switch 1616, a battery indicator 1618, and a battery test points 1620.

Actuation of the on/off switch 1616 activates the end-to-end test circuitry 1602 of a ruggedized, intercommunication system cable test unit. An intercommunication system cable may be coupled to one of the first aircraft ICS connector 1610, the second aircraft ICS connector 1612, or the third aircraft ICS connector 1614. In the example, the first aircraft ICS connector 1610 may correspond to a UH-60 M aircraft, a CH-47 F aircraft ICS cable may connect to the second aircraft ICS connector 1612, the third aircraft ICS connector 1614 may correspond to both a UH-60 L aircraft or an AH-64 E aircraft.

The connector circuits 1604 may be circuits for indicator lights, resistors, other circuit elements, and the like that enable the end-to-end test circuitry 1602 to present test results for an ICS when one end of the ICS is coupled to the first aircraft ICS connector 1610, second aircraft ICS connector 1612 or third aircraft ICS connector 1614 and a second end is coupled to an audio jack that couples to the audio jack circuits 1608. Of course, other aircraft connectors may be accommodated.

The end-to-end test circuitry 1602 also has the capability to provide test result visual indications, test result audio indications, or both. A mode switch (not shown) may be coupled to the mode indicator 1606 and depending upon the selected mode(s) an indicator light may be illuminated.

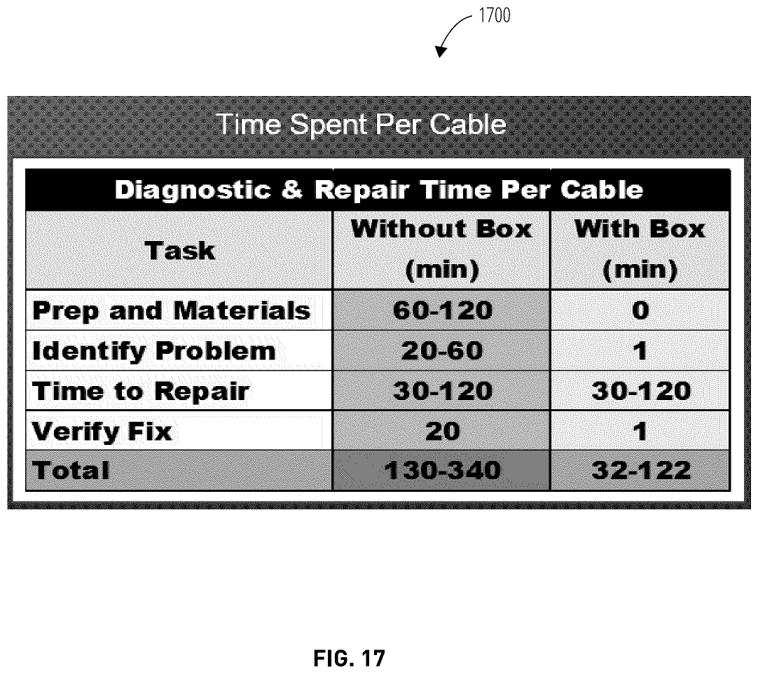

FIG. 17 illustrates exemplary time-saving aspects derived from using the disclosed subject matter. The benefits provided by the examples disclosed are illustrated in the table 1700 that indicates the improvement in repair times.

The following is a glossary of the terms used herein:

“Alignment point” refers to a feature on a connection point that enables the connector of a specific intercommunication system cable to be properly connected to a connection point on the ruggedized, intercommunication system cable test unit for testing.

“Audio jack” refers to an audio connection device of the end-to-end test circuitry that connects to the intercommunication system cable.

“Communication system connector” refers to a connector that is the same as the military-specific connector onboard a military aircraft for interfacing with the communication system of the military aircraft.

“Connection point” refers to connections on the ruggedized, intercommunication system cable test unit that are configured to couple with a first end and second end of an intercommunication system cable to the enable an electrically secure connection to the end-to-end test circuitry. The connection points are substantially the same as the communication system connector. The respective connection points may be different from one another to accommodate differences in the first end and the second end of the intercommunication system cable.

“End-to-end test circuitry” refers to a test device that is operable to test the integrity of an intercommunication system cable from a first end to a second end.

“Fastening elements” refers to structural features such as threads, spring-locks, compression pieces, frictional holding elements and the like. In the context of this subject matter, the fastening elements are configured to maintain a connection between the connection points on the intercommunication system cable and the inputs of the end-to-end test circuitry.

“Integrity” refers to structural capability of an intercommunication system cable to carry signals per the specifications of the intercommunication system cable. Integrity can be categorized as either ‘intact” (alternatively, “operational”) meaning the structural and operational capability of the intercommunication system cable remains within specifications, or “degraded” meaning the structural capability of the intercommunication system cable is not within specifications. “Degraded integrity” can be caused by structural defects such as “open” circuits which include breaks in wires of the intercommunication system cable along the length of the cable or at connectors coupled to the wires at either end of the intercommunication system cable.

“Intercommunication system cable” refers to a wired cable that connects an aircraft crew member headset to an aircraft's communication system to facilitate in-aircraft communication and depending upon configuration of the aircraft's communication system communication with entities external to the aircraft. The wired cable may terminate in connectors at both ends of the length of cable. A first end may terminate in a predetermined military-specified communication connector and a second end that terminates in an audio jack. The intercommunication system cable may have various lengths from a few feet to tens of feet long.

“Outer surface” refers to an edge of a connection point that has alignment features to enable a first end connector of an intercommunication system cable to be properly connected to the connection point of the ruggedized, intercommunication system cable test unit for testing.

“Output devices” refers to a number of indicator lights, such as one or more light emitting diodes, and an audio indicator, such as speaker, buzzer, clicking device, or the like.

“Power source” refers to a replaceable battery, a rechargeable battery, or the like within the end-to-end test circuitry and is configured to provide voltage and current sufficient to test the integrity of the intercommunication system cables.

“Predetermined military-specified communication connector” refers to connectors that are specific to a respective military aircraft's communication system. For example, different aircraft such as the UH-60 M (“Blackhawk”), CH-47 (“Chinook”), AH-64 E (“Apache”) and UH-60 L helicopters have communication system connectors that are different from one another. The intercommunication system cable may have a first end that terminates with a predetermined military-specified communication connector.

“Replaceable battery” refers to power source for the end-to-end test circuitry that has electrical specifications that enable testing of the integrity of the intercommunication system cable.

“Ruggedized, intercommunication system cable test unit” refers to a test device including end-to-end test circuitry, an audio jack, and a communication system connector. A physical shock-resistant, electrical shock-resistant, and/or water-resistant (i.e., ruggedized) housing may be configured to contain the end-to-end test circuitry, audio jack and communication system connector.

“Switch” refers to any form of multi-pole switch, array of switches, or multiplexer that enables the management of connections for test signal pathways whenever an intercommunication system cable is being tested.

“Test signal” refers to a set voltage or voltage signal (e.g., a 5 V square wave of a predetermined frequency) that is generated by applied by the end-to-end test circuitry to the intercommunication system cable.

“Test signal pathway” refers to a path the test signal takes through the intercommunication system cable when the intercommunication system cable is being tested using the ruggedized, intercommunication system cable test unit.

Additional features are also envisioned and may be incorporated into one or more of the foregoing examples or embodiments of the ruggedized, intercommunication system cable test unit and/or end-to-end test circuitry.

Improved strength and organization may be obtained by using DIN rail mounted terminal blocks/splicing connectors instead of loose Wago™ type lever splices, wire nuts, or other forms of splices.

A single simple PCB mounting all LEDs, resistors, and diodes would eliminate most of the wiring and mechanical assembly, with connectors or PCB terminals for connector cable connections is one option. The board can be strong, due to a 0.090 or 0.125 inch thickness, and also be double sided with easily visible traces, and have schematic/debug information on the silkscreen. However, in other examples, the end-to-end test circuitry with connectors and the like may be implemented using more than one PCB.

The described test process may also be modified by the addition of operation amplifiers and comparators to the end-to-end test circuitry for each line (corresponding to a unique aircraft connection point). The modified process may include driving a known current through the cable being tested. An indicator LED and related circuitry may be configured to and be operable to indicate an acceptably low resistance, rather than conductivity. Such an implementation may require additional circuitry components.

In another aspect, the number of separate indicator LEDs may be reduced by utilizing only a specific cable implementation such as 1006 of FIG. 10B, as a result only 5 indicator LEDs are needed as opposed to the 15 separate indicator LEDs of the multi-cable test unit. The reduction in the number of indicator LEDs may also be reduced by implementing a microcontroller-based design with an analog-to-digital converter (ADC). For example, a fixed voltage or current source may be used and an ADC of a microcontroller may be operable to determine the cable/connector resistance on each line, then lighting the indicating LEDs accordingly. This is fewer parts, but requires firmware and is more difficult to understand and troubleshoot for those not familiar with microcontroller designs and firmware.

It is also envisioned that intermittent connection testing may be added. For example, the quick flashes of an LED are difficult to see when there is an intermittent connection. An intermittent connection may be identified by incorporating in the end-to-end circuitry a timer/one-shot circuit that will keep an indicator LED from turning off for about 1 second or longer when there is any break in the connection, making it much more visible. The cables may need to be wiggled or stressed to assure confirm any short break would result in crackling on the audio connection. The timer may be a 555 timer or the like, and additional digital logic gates per line, with the resistors and capacitors may be added for proper timing. Alternatively, a microcontroller-based design may be able to implement this feature without any added components, just some additional firmware.

Short circuit testing is also envisioned and allows the test unit to identify short circuits to the shield (insulating and protective cover surrounding the intercommunication system cable) and signal-to-signal short circuits as well as open circuits. This is normally done by scanning the pins, driving one line, and checking all of the others for the expected pattern. The current design has the diodes at the audio jack end to allow the use of a digital voltage meter to be used with the test points to check for shorts, but this is a manual process that takes 5-10 seconds and may be prone to errors. Automatic short testing could be done in a variety of ways, for instance with individual line push buttons as the simplest example. It is also possible to use an analog resistance approach to set different reference values (i.e., reference resistance values in ohms) for each line (using, for example, a potentiometer or the like), and using window comparators that find lines with resistance that is too low as well as resistance that is too high in comparison to the respective reference values for each line. In an example, a measurement of nearly 0 ohms when compared to a reference value range (e.g., 0.0-0.5 ohms) may indicate low resistance and sufficient continuity (i.e., a “good” ICS cable) when the resistance of a single wire of the cable is measured end to end, while measurement of approximately a few ohms (e.g., a reference value range may be set at 3.0 ohms or less) may indicate higher resistance and likely insufficient continuity (i.e., a “bad” ICS cable) when the resistance of the respective single wire of the cable is measured end to end. Alternatively, when measuring for a short circuit between one or more wires of a cable or a short circuit to ground, the expected ohmic value range is a high ohmic value (such as “infinity” or hundreds of thousands of ohms). When a first end of one wire of the cable is coupled for measurement and a second end of another wire, different from the first wire of the cable is coupled for measurement, the reference value range is the high ohmic value. If the measurement indicates a low ohmic value, such as thousands of ohms or 0.0 ohms, the low ohmic value indicates a short circuit. The system is also configured to measure short circuits to “ground” attachment points for the cable. For example, the measurement of approximately a few ohms may be indicative of a short circuit to ground.

Audio path testing may be incorporated by adding a tone generator and a speaker/amplifier to the end-to-end circuitry. For example, a test signal may an audible tone generated by the tone generator, and the end-to-end test circuitry may include an audio indicator, such as a speaker, to output the audible tone after the audible tone test signal is applied to the intercommunication system cable via the end-to-end test circuitry. More specifically, the signal generated by the tone generator may be routed through both the microphone and speaker cable paths of the intercommunication system cable. In a specific example, a small signal through the microphone signal path, then connecting it to the amplifier that is routed through the speaker path, then goes to the speaker. In the example, buttons or isolation devices to determine which of the paths (microphone or speaker) are causing the issue may be provided. The use of different push-to-talk (PTT) test points as shown in the figures may also be used to determine which paths are at issue. In addition, the total harmonic distortion (THD) of the final signal may be electrically measured. The connections between all of the various components of the cable under test has to be managed, so that the normal cable testing as well as the audio path testing can be done without interference. A large multi-pole switch may be work, such as an analog multiplexer integrated circuit, or a pin and firmware arrangement of a microcontroller may be used in the measurement of the THD of the final signal. For example, a circuit that capacitively couples a timer output for the microphone drive, and then selecting the amplifier input/enable using additional pins may be used.

Adding fault location is a process by which locations are identified in the intercommunication system cable at which an open circuit or short circuit occurs may also be implemented. Most often, the failure is an open circuit at one end or the other of the cable, but mid-cable breaks (i.e., open circuits) or short circuits are also possible. High-end test equipment uses TDR (time-domain reflectometry) for fault location, which detects the impedance mismatch of the open circuit or short circuit using the speed of light (electricity) to measure the distance from the signal injection end of the cable. The challenge with TDR is that it requires fast, high-resolution ADC and processing, and usually a graphic display to show the likely position based on the reflected waveform. The complexity, development cost, and build cost of a TDR system is quite high, and difficult to justify for this project. A much simpler and low-cost approach is to use the common wire tracing technique of injecting a low frequency AC signal on the open wire, then use a high impedance audio amplifier with a short probe antenna to inductively couple the electro-magnetic force (EMF) from the wire. This is typically done by injecting a 1 KHz to 3 KHz 5V square wave on the wire, then have a hand-held probe with the audio amp, speaker, and pick-up antenna in it. Because the cables are shielded, there may be instances of signal leak which may need to be compensated for if necessary. The fault location test feature can be implemented by integrating circuitry in the end-to-end test circuitry to accommodate an over-the-counter wire tracer. In a fully manual/analog design, this may require switches or some other switching array to select function and line/wire.

Some of the foregoing examples show a toggle switch to turn the ruggedized, intercommunication system cable test unit on and off. Without any cable attached, the only load on the power source is the power LED (i.e., the indicator LED indicating the unit is “on” and ready to be used for testing). It is envisioned that this load which may be drain the battery if the switch is left in the “on” position accidentally, may be eliminated. For example, when no cable is detected, the unit may not turn “on.” An automatic “ON” circuit may detect the cable shield or other part of the intercommunication system cable to detect that a cable is attached to the ruggedized, intercommunication system cable test unit. This would eliminate the need for an on/off switch, and the risk that it is left on to drain the battery.

An additional analog comparator circuit can monitor the battery voltage and provide an indicator of the battery level. The foregoing examples provide test points for the power source that enable measuring of the voltage level with a meter. In a microcontroller based design, the common approach is to put the system in a very low power state, and provide a momentary wake-up button to power the unit on, with a timeout of 1-2 minutes of inactivity to shut it off. The low power mode is likely to only pull 20 uA or so from the battery, so a typical 9 V, 800 mAh battery that would potentially last 25,000 hours or almost 3 years, on standby.

Beyond a simple manual tester approach discussed herein, additional improvements may include using PCB mounted terminal blocks, connectors, or soldering wires to interface to the mating cable connectors, and adding circuits to eliminate the need for the power switch, monitor for low battery, and other simple features.

Examples of end-to-end test circuitry using a microcontroller may include a microcontroller and appropriate interface circuits to drive and sense the cable ends, and display the result of the test.

It is also envisioned that the microcontroller-based end-to-end test circuitry may execute open circuit, short circuit, resistance, and intermittent test modes continuously and substantially simultaneously, if desired, without user selection, using multi-color LEDs and different indications, such as flashing or beeping, if needed to indicate the line and the type of fault (e.g., open circuit, short circuit, high resistance, intermittent connection, or the like). The fault identification and audio path modes described above may be implemented using selector buttons to select the respective mode, although the fault identification and audio path modes may auto-sequence and stop on failure.

Certain examples of the present disclosure were described above. It is, however, expressly noted that the present disclosure is not limited to those examples, but the intention is that additions and modifications to what was expressly described herein are also included within the scope of the disclosed examples. Moreover, it is to be understood that the features of the various examples described herein were not mutually exclusive and may exist in various combinations and permutations, even if such combinations or permutations were not made express herein, without departing from the spirit and scope of the disclosed examples. In fact, variations, modifications, and other implementations of what was described herein will occur to those of ordinary skill in the art without departing from the spirit and the scope of the disclosed examples. As such, the disclosed examples are not to be defined only by the preceding illustrative description.

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, various features are grouped together in a single example for streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels and are not intended to impose numerical requirements on their objects.

The foregoing description of examples has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but by the claims appended hereto. Future filed applications claiming priority to this application may claim the disclosed subject matter in a different manner and may include any set of one or more limitations as variously disclosed or otherwise demonstrated herein.

What is claimed is:

1. A ruggedized, intercommunication system cable test unit, comprising:
end-to-end test circuitry;
a power source;
output devices including light sources or an audio source; and
one or more connection points, coupled to the end-to-end test circuitry, operable to couple with military-specified communication cable connectors of an intercommunication system cable, the one or more connection points including a respective input configured to receive a respective pin of a predetermined military-specified communication cable connector,
wherein the end-to-end test circuitry is operable to:
apply a test signal at the respective input to each respective pin of the predetermined military-specified communication connector;
generate an output signal based on receipt of the applied test signal; and
apply the output signal to the output device indicating a response of the end-to-end test circuitry to the applied test signal.

2. The ruggedized, intercommunication system cable test unit of claim 1, wherein each respective pin is specific to a military-specified communication cable connector used in a specific military aircraft, wherein the inputs enable connection of the intercommunication system cable to the ruggedized, intercommunication system cable test unit.

3. The ruggedized, intercommunication system cable test unit of claim 1, wherein one or more connection points, comprises:
an outer securing mechanism configured to secure the military-specified communication cable connector to an outer surface of the ruggedized, intercommunication system cable test unit.

4. The ruggedized, intercommunication system cable test unit of claim 3, wherein the outer securing mechanism includes:
fastening elements operable to secure the military-specified communication cable connector to the outer surface of the ruggedized, intercommunication system cable test, wherein the fastening elements include one or more of: a latch, threads, a threaded coupling, a compression latch, or a spring-based latch.

5. The ruggedized, intercommunication system cable test unit of claim 1, wherein the one or more connection points, comprises:
a first connection point having a helicopter-specific connector; and
an audio jack of a headset including a signal path for at least one audio speaker and another signal path for a microphone.

6. The ruggedized, intercommunication system cable test unit of claim 1, wherein the power source comprises a replaceable battery.

7. The ruggedized, intercommunication system cable test unit of claim 1, wherein the end-to-end test circuitry comprises:
a switch operable to apply a test signal to each respective test signal pathway of a plurality of test signal pathways between the audio jack and the communication system connector, wherein the switch is configured to apply the test signal to the respective test signal pathways corresponding to the predetermined military-specified communication connector.

8. The ruggedized, intercommunication system cable test unit of claim 1, further comprising:
a top surface including test points and the light sources, wherein the test points are configured to measure resistance of a portion of the communication cable coupled to the respective pin of the predetermined military-specified communication connector.

9. A ruggedized, intercommunication system cable test unit, comprising:
an audio jack operable to connect to an audio connection end of an intercommunication system cable;
a communication system connector operable to connect to a communication system connector of the intercommunication system cable, wherein the communication system connector is specific to a type of military aircraft and the communication system connector connects a plurality of pins of the intercommunication system cable for testing; and
end-to-end test circuitry configured to test integrity of an intercommunication system cable when the intercommunication system cable is coupled to the audio jack and the communication system connector, wherein the end-to-end test circuitry is operable to: detect whether an open circuit is present in the intercommunication system cable; and in response to detecting presence of the open circuit, produce an output indicating the presence of the open circuit.

10. The ruggedized, intercommunication system cable test unit of claim 9, wherein:
the communication system connector includes a plurality of communication system connectors disposed in a housing of the ruggedized, intercommunication system cable test unit, and
each communication system connector comprises:
one or more inputs configured to:
link with the plurality of pins of the intercommunication system cable for a specific type of military aircraft, and
couple to the end-to-end test circuitry,
wherein when the end of the intercommunication system cable is secured to the communication system connector, the one or more inputs are part of a respective test signal pathway to the audio connection end of the intercommunication system cable.

11. The ruggedized, intercommunication system cable test unit of claim 9, further comprising:
a plurality of indicator lights coupled to the end-to-end test circuitry, wherein each respective indicator light of the plurality of indicator lights provides an indication of the open circuit, when present, for a respective test signal pathway.

12. The ruggedized, intercommunication system cable test unit of claim 9, further comprising:
an audio indicator coupled to the end-to-end test circuitry, wherein the audio indicator provides an indication of the open circuit, when present, for a respective test signal pathway.

13. The ruggedized, intercommunication system cable test unit of claim 9, wherein the end-to-end test circuitry comprises:
a switch operable to apply a test signal to each respective test signal pathway of a plurality of test signal pathways between the audio jack and the communication system connector.

14. The ruggedized, intercommunication system cable test unit of claim 13, wherein: the test signal is an audible tone, and
the end-to-end test circuitry includes a speaker to output the audible tone after traversing an intercommunication system cable connected between the audio jack and the communication system connector.

15. A method of using a ruggedized, intercommunication system cable test unit to test the integrity of an intercommunication system cable, the method comprising:
coupling a first end of a military aircraft specific communication cable to a communication system connector of the ruggedized, intercommunication system cable test unit specific to the military aircraft specific communication cable;
coupling a second end of the military aircraft specific communication cable to an audio jack of the ruggedized, intercommunication system cable test unit;
applying a test signal by end-to-end test circuitry of the intercommunication system cable test device to the military aircraft specific communication cable; and
generating an indication of the open circuit status of the military aircraft specific communication cable.

16. The method of claim 15, when applying the audio test signal by the end-to-end circuitry, further comprises:
in response to selection of a test device setting corresponding to an aircraft type of the military aircraft specific communication cable, setting a switch configuration coupling respective inputs of the communication system connector to which the first end of the military aircraft specific cable is coupled; and
switching the application of the audio test signal among the respective inputs of the communication system connector.

17. The method of claim 15, when generating the indication of the open circuit status of the military aircraft specific communication cable, further comprises:
illuminating a visual indication of the open circuit status;
emitting an audio indication of the open circuit status; or
both.

18. The method of claim 15, when generating the indication of the open circuit status of the military aircraft specific communication cable, further comprises:
causing a visual indication of the open circuit status to be generated, wherein the visual indication includes a respective light emitting diode of a plurality of light emitting diodes being numbered to correspond to a distinct signal path through the military aircraft specific communication cable that is faulty.

19. The method of claim 18, further comprising:
holding the visual indication of the open circuit status of the distinct signal path until the ruggedized, intercommunication system cable test unit is reset.

20. The method of claim 15, when generating the indication of the open circuit status of the military aircraft specific communication cable, further comprises:
producing an audible signal representative of the audio test signal via an audio device.
